(19) United States
(12) Patent Application Publication
(10) Pub. No.: US 2025/0142227 A1
(43) Pub. Date: May 1, 2025

(54) IMAGING DEVICE AND METHOD FOR DRIVING THE SAME

(71) Applicant: SONY SEMICONDUCTOR SOLUTIONS CORPORATION, KANAGAWA (JP)

(72) Inventors: YUKI HATTORI, KANAGAWA (JP); YORITO SAKANO, KANAGAWA (JP)

(21) Appl. No.: 18/834,809

(22) PCT Filed: Dec. 20, 2022
(86) PCT No.: PCT/JP2022/046885

§ 371 Date: Jul. 31, 2024

(30) Foreign Application Priority Data
Feb. 8, 2022 (JP) 2022-018255

(51) Int. Cl. H04N 25/59; H04N 25/709; H04N 25/771

(52) U.S. Cl. CPC H04N 25/59; H04N 25/709; H04N 25/771

(57) ABSTRACT

An imaging device of one embodiment of the present disclosure includes: a plurality of pixels each including a first photoelectric converter configured to generate an electric charge by photoelectric conversion, an accumulation unit configured to accumulate an electric charge into which light has been photoelectrically converted, a capacitive element configured to accumulate an overflowed electric charge, a first transistor provided between the capacitive element and the accumulation unit, and a second transistor configured to output a signal based on the electric charge accumulated in the accumulation unit; and a signal line coupled to the second transistors of the plurality of pixels.

### TECHNICAL FIELD

The present disclosure relates to an imaging device and a method for driving the imaging device.

### BACKGROUND ART

There has been proposed an imaging device that includes two floating diffusion (FD) and performs readout of low-volume data and readout of high-volume data (PTL 1).

### CITATION LIST

### Patent Literature

PTL 1: International Publication No. WO2018/110303

### SUMMARY OF INVENTION

Improvement of a dynamic range is expected of an imaging device.

It is desired to provide an imaging device that makes it possible to improve the dynamic range.

An imaging device of an embodiment of the present disclosure includes: a plurality of pixels each including a first photoelectric converter configured to generate an electric charge by photoelectric conversion, an accumulation unit configured to accumulate an electric charge into which light has been photoelectrically converted, a capacitive element configured to accumulate an overflowed electric charge, a first transistor provided between the capacitive element and the accumulation unit, and a second transistor configured to output a signal based on the electric charge accumulated in the accumulation unit; and a signal line coupled to the second transistors of the plurality of pixels.

A method for driving an imaging device of an embodiment of the present disclosure, the imaging device including a plurality of pixels each including a photoelectric converter configured to generate an electric charge by photoelectric conversion, an accumulation unit configured to accumulate an electric charge, a capacitive element configured to accumulate an overflowed electric charge, and a transistor configured to output a signal based on the electric charge accumulated in the accumulation unit and a signal line coupled to the transistors of the plurality of pixels, includes: transferring at least one of the electric charge into which light has been photoelectrically converted by the photoelectric converter and the electric charge accumulated in the capacitive element to the accumulation unit; and outputting, by the transistor, a signal based on the electric charge accumulated in the accumulation unit to the signal line.

### BRIEF DESCRIPTION OF DRAWINGS

FIG. 1 is a diagram illustrating an example of a schematic configuration of an electronic apparatus according to a first embodiment of the present disclosure.

FIG. 2 is a diagram illustrating an example of a schematic configuration of an imaging device according to the first embodiment of the present disclosure.

FIG. 3 is a diagram illustrating an example of a circuit configuration of a pixel of the imaging device according to the first embodiment of the present disclosure.

FIG. 4 is a diagram illustrating an example of a layout of the pixel of the imaging device according to the first embodiment of the present disclosure.

FIG. 5 is a diagram illustrating another example of the layout of the pixel of the imaging device according to the first embodiment of the present disclosure.

FIG. 6 is a timing chart illustrating an example of operation of the imaging device according to the first embodiment of the present disclosure.

FIG. 7 is a timing chart illustrating another example of the operation of the imaging device according to the first embodiment of the present disclosure.

FIG. 8 is a diagram illustrating an example of a cross-sectional configuration of the imaging device according to the first embodiment of the present disclosure.

FIG. 9 is a diagram illustrating another example of the cross-sectional configuration of the imaging device according to the first embodiment of the present disclosure.

FIG. 10 is a diagram illustrating an example of a circuit configuration of a pixel of an imaging device according to Modification Example 1 of the present disclosure.

FIG. 11 is a diagram illustrating another example of the circuit configuration of the pixel of the imaging device according to Modification Example 1 of the present disclosure.

FIG. 12 is a diagram illustrating an example of a circuit configuration of a pixel of an imaging device according to Modification Example 2 of the present disclosure.

FIG. 13 is a diagram illustrating another example of the circuit configuration of the pixel of the imaging device according to Modification Example 2 of the present disclosure.

FIG. 14 is a diagram illustrating still another example of the circuit configuration of the pixel of the imaging device according to Modification Example 2 of the present disclosure.

FIG. 15 is a diagram illustrating an example of a circuit configuration of a pixel of an imaging device according to a second embodiment of the present disclosure.

FIG. 16 is a timing chart illustrating an example of operation of the imaging device according to the second embodiment of the present disclosure.

FIG. 17 is a timing chart illustrating another example of the operation of the imaging device according to the second embodiment of the present disclosure.

FIG. 18 is a diagram illustrating an example of a circuit configuration of a pixel of an imaging device according to Modification Example 3 of the present disclosure.

FIG. 19 is a diagram illustrating another example of the circuit configuration of the pixel of the imaging device according to Modification Example 3 of the present disclosure.

FIG. 20 is a diagram illustrating an example of a circuit configuration of a pixel of an imaging device according to Modification Example 4 of the present disclosure.

FIG. 21 is a diagram illustrating an example of a circuit configuration of a pixel of an imaging device according to Modification Example 5 of the present disclosure.

FIG. 22 a diagram illustrating another example of the circuit configuration of the pixel of the imaging device according to Modification Example 5 of the present disclosure.

FIG. 23 is a diagram illustrating an example of a circuit configuration of a pixel of an imaging device according to Modification Example 6 of the present disclosure.

FIG. 24 is a block diagram depicting an example of schematic configuration of a vehicle control system.

FIG. 25 is a diagram of assistance in explaining an example of installation positions of an outside-vehicle information detecting section and an imaging section.

FIG. 26 is a view depicting an example of a schematic configuration of an endoscopic surgery system.

FIG. 27 is a block diagram depicting an example of a functional configuration of a camera head and a camera control unit (CCU).

### MODES FOR CARRYING OUT THE INVENTION

With reference to the drawings, embodiments of the present disclosure will be described in detail below. It is to be noted that the description will be made in the following order.
1. First Embodiment
2. Second Embodiment
3. Examples of Use
4. Application Examples

### 1. First Embodiment

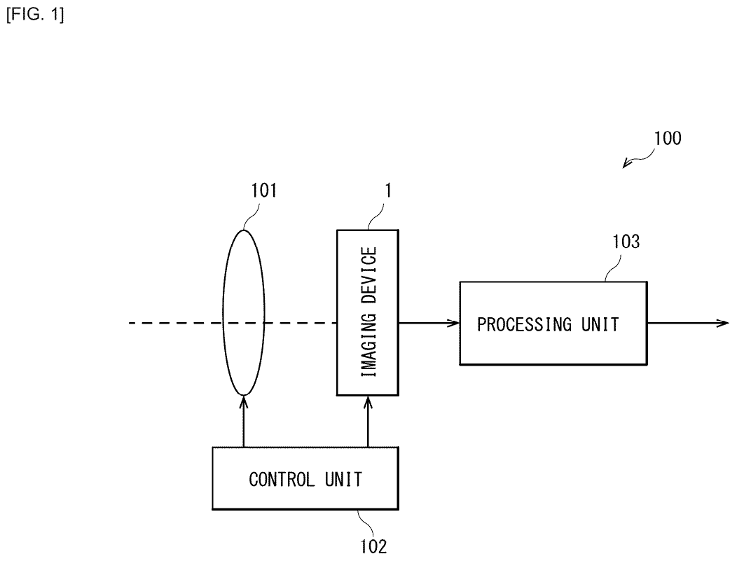

FIG. 1 is a diagram illustrating an example of a schematic configuration of an electronic apparatus according to a first embodiment of the present disclosure. An electronic apparatus 100 includes an imaging device 1, an optical system 101, a control unit 102, and a processing unit 103. The optical system 101 includes an optical lens, and guides light from a subject to the imaging device 1.

The imaging device 1 includes a plurality of pixels each including a photoelectric converter, and is configured to photoelectrically convert light that has entered and generate a signal. The photoelectric converter is, for example, a photodiode (PD), and converts the entered light into an electric charge. The imaging device 1 is, for example, a complementary metal-oxide semiconductor (CMOS) image sensor. The imaging device 1 receives light that has passed through the optical system 101, and captures an image of a subject. The imaging device 1 converts an amount of incident light formed as an image on an imaging plane by the optical system 101 into an electrical signal on a pixel-by-pixel basis, and outputs the electrical signal as a pixel signal.

The control unit 102 is configured to control the operation of the imaging device 1. The control unit 102 controls the imaging device 1 by supplying a control signal to the imaging device 1, and causes the imaging device 1 to output a pixel signal. The processing unit 103 is a signal processing unit, and is configured to perform signal processing on a signal output from the imaging device 1. The control unit 102 and the processing unit 103 include, for example, a processor and a memory (such as a ROM or a RAM), and perform signal processing (information processing) on the basis of a program. The processing unit 103 is, for example, a digital signal processor (DSP). The processing unit 103 may generate image data by performing a variety of signal processing on respective signals of the pixels output from the imaging device 1.

### [Schematic Configuration of Imaging Device]

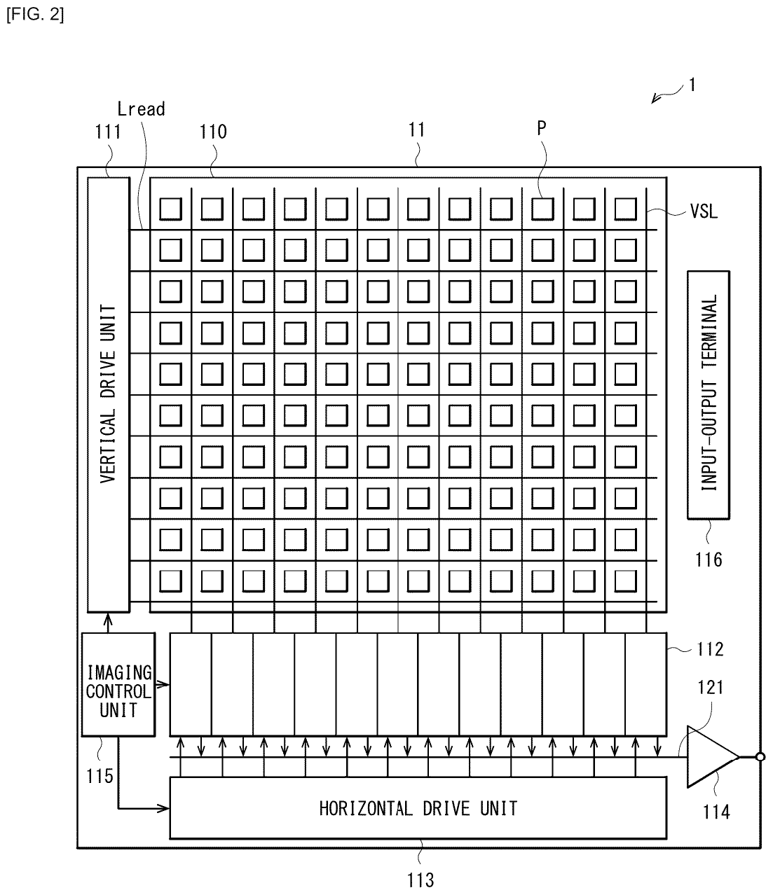

FIG. 2 is a diagram illustrating an example of a schematic configuration of an imaging device according to the first embodiment. As illustrated in FIG. 2, the imaging device 1 includes, as an imaging area, a region (a pixel section 110) of a plurality of pixels P arranged two-dimensionally in a matrix. The imaging device 1 includes, in a region around the pixel section 110, for example, a vertical drive unit 111, a signal processing unit 112, a horizontal drive unit 113, an output unit 114, an imaging control unit 115, an input-output terminal 116, etc.

The plurality of pixels P in the pixel section 110 includes, as an example, pixels (R pixels) each including a filter that allows transmission of light in a red wavelength region, pixels (G pixels) each including a filter that allows transmission of light in a green wavelength region, and pixels (B pixels) each including a filter that allows transmission of light in a blue wavelength region. The R pixels, the G pixels, and the B pixels are arranged, for example, in accordance with a so-called Bayer layout. The R pixels, the G pixels, and the B pixels are configured to generate a pixel signal of an R component, a pixel signal of a G component, and a pixel signal of a B component, respectively. It is possible to obtain R, G, and B pixel signals on the basis of respective electric charges into which light has been photoelectrically converted in the R, G, and B pixels.

It is to be noted that the filters provided in the pixels P are not limited to color filters of primary colors (RGB), and may be color filters of complementary colors, for example, cyan (Cy), magenta (Mg), and yellow (Ye) or some other colors. Furthermore, a color filter corresponding to white (W), i.e., a filter that allows transmission of light in all wavelength regions of incident light may be provided.

The imaging device 1 is provided with, for example, multiple pixel drive lines Lread and multiple vertical signal lines VSL. For example, in the pixel section 110, the multiple pixel drive lines Lread are provided, one for each pixel row including multiple pixels P aligned in a horizontal direction (a row direction). Furthermore, in the pixel section 110, the vertical signal lines VSL are provided, one for each pixel column including multiple pixels P aligned in a vertical direction (a column direction). The pixel drive lines Lread are configured to transmit drive signals (signals STGL, SRST, SFDG, SFCG, etc. to be described later) for readout of a signal from a pixel P. The vertical signal lines VSL are configured to transmit a signal output from a pixel P.

The vertical drive unit 111 includes a shift register, an address decoder, etc. The vertical drive unit 111 is configured to drive each pixel P in the pixel section 110. The vertical drive unit 111 is a pixel drive unit, and generates a signal for driving a pixel P and outputs the signal to each pixel P in the pixel section 110 through the pixel drive line Lread. For example, the vertical drive unit 111 generates a signal STGL to control a transfer transistor, a signal SRST to control a reset transistor, etc. and supplies the signals to each pixel P through the pixel drive line Lread.

The signal processing unit 112 is configured to perform signal processing on an signal input from a pixel. The signal processing unit 112 includes, for example, a load circuit unit coupled to the vertical signal lines VSL, analog-digital converters (ADCs) provided one for each vertical signal line VSL, a horizontal selection switch, etc. Together with amplifier transistors of the pixels P, the load circuit unit constitutes part of a source follower circuit. It is to be noted that the signal processing unit 112 may include an amplifier circuit unit configured to amplify a signal read out from a pixel P through the vertical signal line VSL.

A signal output from each pixel P selected and scanned by the vertical drive unit 111 is supplied to the signal processing unit 112 through the vertical signal line VSL. For example, the signal processing unit 112 performs signal processing such as analog-digital (AD) conversion and correlated double sampling (CDS).

The horizontal drive unit 113 includes a shift register, an address decoder, etc. The horizontal drive unit 113 is configured to drive each horizontal selection switch of the signal processing unit 112. The horizontal drive unit 113 drives each horizontal selection switch of the signal processing unit 112 in turn while scanning. A signal of each pixel P transmitted through each of the vertical signal lines VSL is subjected to signal processing by the signal processing unit 112, and is output to a horizontal signal line 121 in turn through selective scanning by the horizontal drive unit 113.

The output unit 114 is configured to perform signal processing on an input signal and output the processed signal. The output unit 114 performs signal processing on signals of pixels sequentially input from each of the signal processing units 112 through the horizontal signal line 121, and outputs the processed signals. For example, the output unit 114 performs only buffering in some cases, and performs black level adjustment, column variation correction, a variety of digital signal processing, etc. in other cases.

A circuit part including the vertical drive unit 111, the signal processing unit 112, the horizontal drive unit 113, the horizontal signal line 121, and the output unit 114 may be formed on a semiconductor substrate 11, or may be provided in an external control IC. Furthermore, the circuit part may be formed on another substrate coupled by cable or something.

The imaging control unit 115 is configured to control each unit in the imaging device 1. The imaging control unit 115 receives a clock provided from the outside of the semiconductor substrate 11, data to order the operation mode, etc., and outputs data such as internal information of the imaging device 1. The imaging control unit 115 includes a timing generator that generates various timing signals, and performs control of driving peripheral circuits such as the vertical drive unit 111, the signal processing unit 112, and the horizontal drive unit 113 on the basis of various timing signals generated by the timing generator. The input-output terminal 116 exchanges a signal with the outside.

### [Configuration of Pixel]

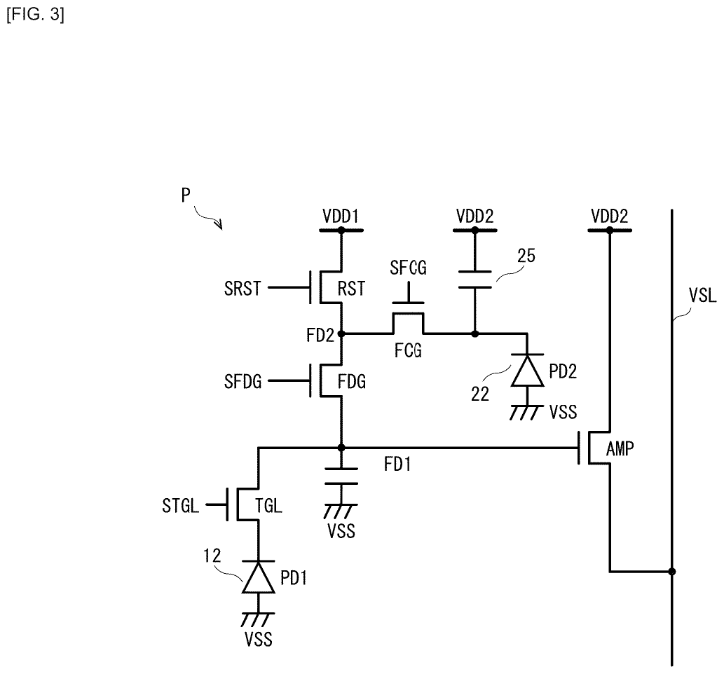

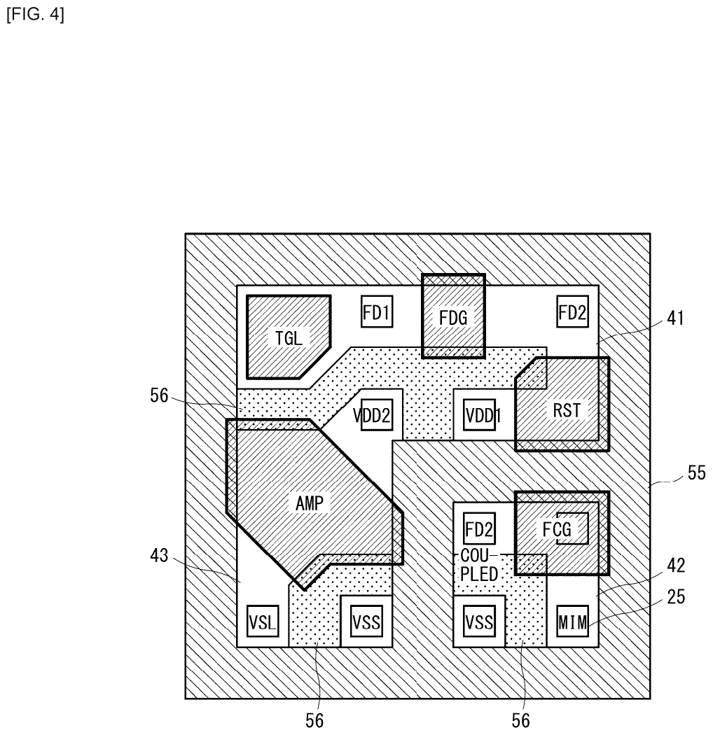

FIG. 3 is a diagram illustrating an example of a circuit configuration of a pixel of the imaging device according to the first embodiment. FIG. 4 is a diagram illustrating an example of a layout of a pixel P. The pixel P includes a first photoelectric converter 12, a transistor TGL, a first floating diffusion (FD1), a transistor AMP, a transistor FDG, a second floating diffusion (FD2), and a transistor RST. Furthermore, the pixel P includes a second photoelectric converter 22, a capacitive element 25, and a transistor FCG.

The transistor TGL, the transistor AMP, the transistor FDG, the transistor RST, and the transistor FCG are each a MOS transistor (MOSFET) having gate, source, and drain terminals. In the example illustrated in FIG. 3, the transistors TGL, AMP, FDG, RST, and FCG each include an NMOS transistor. It is to be noted that the transistors of the pixel P may include a PMOS transistor.

The first photoelectric converter 12 is configured to generate an electric charge by photoelectric conversion. In the example illustrated in FIG. 3, the first photoelectric converter 12 is a first photodiode (PD1), and converts incoming light into an electric charge. The first photoelectric converter 12 performs photoelectric conversion and generates an electric charge according to an amount of received light.

The transistor TGL is configured to transfer an electric charge into which light has been photoelectrically converted by the first photoelectric converter 12 to the first FD1. As illustrated in FIG. 3, the transistor TGL is controlled by a signal STGL, and electrically couples or decouples the first photoelectric converter 12 and the first FD1. The transistor TGL is a transfer transistor, and may transfer the electric charge into which light has been photoelectrically converted and accumulated by the first photoelectric converter 12 to the first FD1.

The first FD1 is a first accumulation unit, and is configured to accumulate a transferred electric charge. The first FD1 may accumulate electric charges into which light has been photoelectrically converted by the first and second photoelectric converters 12 and 22. The first FD1 may be said to be a charge holding unit that holds the transferred electric charge. The first FD1 accumulates the transferred electric charge, and converts the electric charge into a voltage according to the capacitance of the first FD1.

The transistor AMP is configured to output a signal based on the electric charge accumulated in the first FD1 to the vertical signal line VSL. As illustrated in FIG. 3, a gate of the transistor AMP is electrically coupled to the first FD1, and the voltage converted by the first FD1 is input to the gate of the transistor AMP. A drain of the transistor AMP is coupled to a power supply line supplied with a power supply voltage VDD2. The drain of the transistor AMP is provided with the power supply voltage VDD2 from a voltage source through that power supply line. A source of the transistor AMP is coupled to the vertical signal line VSL. The transistor AMP is an amplifier transistor, and may generate a signal based on the electric charge accumulated in the first FD1, i.e., a signal based on the voltage of the first FD1 and output the generated signal to the vertical signal line VSL.

The transistor FDG is configured to couple the first FD1 and the second FD2. As illustrated in FIG. 3, the transistor FDG is controlled by a signal SFDG, and electrically couples or decouples the first FD1 and the second FD2. The transistor FDG is controlled to be on/off by the signal SFDG, and may electrically couple the first FD1 and the second FD2.

In a case where the transistor FDG is in an off-state, the first FD1 and the second FD2 are electrically decoupled, and the electric charge transferred from the first photoelectric converter 12 is accumulated in the first FD1. In a case where the transistor FDG is in an on-state, the first FD1 and the second FD2 are electrically coupled, and the electric charge transferred from the first photoelectric converter 12 is accumulated in the first FD1 and the second FD2. When the transistor FDG goes into the on-state, the capacitance added to the first FD1 becomes larger, which makes it possible to change the conversion efficiency (the gain) of when an electric charge is converted into a voltage. The transistor FDG may be said to be a switching transistor that switches the capacitance coupled to the gate of the transistor AMP and changes the conversion efficiency.

The second FD2 is a second accumulation unit, and is configured to accumulate a transferred electric charge. The second FD2 may accumulate electric charges into which light has been photoelectrically converted by the first and second photoelectric converters 12 and 22. The second FD2 may be said to be a charge holding unit that holds the transferred electric charge. The second FD2 accumulates the transferred electric charge, and converts the electric charge into a voltage according to the capacitance of the second FD2.

The transistor RST is configured to reset a voltage of the first FD1 and a voltage of the second FD2. The transistor RST is electrically coupled to a power supply line and voltage source configured to selectively transmit multiple different voltages, and is configured to perform a reset of the electric charge of the pixel P. A value of power supply voltage supplied to the transistor RST is configured to be switched, for example, between a first voltage and a second voltage (a low-level voltage) lower than the first voltage. The second voltage may be, for example, a ground voltage.

In the example illustrated in FIG. 3, of a source and a drain of the transistor RST, one is coupled to the second FD2, and the other one is coupled to a power supply line through which a power supply voltage VDD1, which is configured to be set to a high voltage or a low voltage, is configured to be supplied. The other one of the source and the drain of the transistor RST is provided with the high-level or low-level power supply voltage VDD1 from the voltage source through that power supply line. The power supply line and voltage source coupled to the transistor RST may selectively output a high-potential power supply voltage VDD1 or a low-potential power supply voltage VDD1.

The transistor RST is controlled by a signal SRST, and may reset the electric charges accumulated in the first FD1 and the second FD2 and reset the voltages of the first FD1 and the second FD2. The transistor RST is a reset transistor. In a case of performing a reset on the pixel P, for example, the power supply line coupled to the transistor RST is provided with the high-level power supply voltage VDD1. The transistors RST and FDG make it possible to supply the high-level power supply voltage VDD1 to the first FD1 and the second FD2. The transistor RST may electrically couple the power supply line applied with the high-level power supply voltage VDD1 and the first FD1 through the transistor FDG and discharge the electric charge accumulated in the first FD1.

The second photoelectric converter 22 is configured to generate an electric charge by photoelectric conversion. In the example illustrated in FIG. 3, the second photoelectric converter 22 is a second photodiode (PD2), and converts incoming light into an electric charge. The second photoelectric converter 22 performs photoelectric conversion and generates an electric charge according to an amount of received light.

The first and second photoelectric converters 12 and 22 of the pixel P are configured to have different sensibilities to incoming light from each other. In the present embodiment, the sensibility of the second photoelectric converter 22 to light is lower than the sensibility of the first photoelectric converter 12 to light. For example, a light receiving area of the second photoelectric converter 22 is smaller than a light receiving area of the first photoelectric converter 12, and thus an amount of light received by the second photoelectric converter 22 is smaller than an amount of light received by the first photoelectric converter 12.

The second photoelectric converter 22 has a lower sensibility than the sensibility of the first photoelectric converter 12; thus, even after an amount of electric charge accumulated in the first photoelectric converter 12 in a charge accumulation period (an exposure period) is saturated, it is possible to generate and accumulate an electric charge according to incident light. It is to be noted that the sensibility of the second photoelectric converter 22 may be lowered by providing a filter that reduces the intensity of incoming light (a neutral density filter) on the second photoelectric converter 22.

The capacitive element 25 is configured to accumulate an overflowed electric charge. The capacitive element 25 includes, for example, a capacitive element such as a MOS capacitor or a metal-insulator-metal (MIM) capacitor. The capacitive element 25 accumulates an electric charge overflowed from the second photoelectric converter 22. In the example illustrated in FIG. 3, one of electrodes of the capacitive element 25 is electrically coupled to the second photoelectric converter 22. Furthermore, the other electrode of the capacitive element 25 is coupled to the power supply line supplied with the power supply voltage VDD2. The other electrode of the capacitive element 25 is provided with the power supply voltage VDD2 from the voltage source through that power supply line. The capacitive element 25 may hold an electric charge overflowed from the second photoelectric converter 22.

The pixel P is provided with the capacitive element 25; thus, even in a case of the occurrence of an electric charge exceeding an amount of electric charge allowed to be accumulated in the second photoelectric converter 22 (a saturated charge amount), it is possible to accumulate an electric charge overflowed from the second photoelectric converter 22 in the capacitive element 25. Therefore, it is possible to obtain a signal according to an electric charge obtained by adding the electric charge accumulated in the second photoelectric converter 22 and the electric charge accumulated in the capacitive element 25.

The transistor FCG is configured to couple the capacitive element 25 and the second FD2. As illustrated in FIG. 3, the transistor FCG is controlled by a signal SFCG, and electrically couples or decouples the capacitive element 25 and the second FD2. The transistor FCG is controlled to be on/off by the signal SFCG, and electrically couples or decouples the capacitive element 25 and the second FD2. The transistor FCG may transfer electric charges accumulated in the capacitive element 25 and the second photoelectric converter to the second FD2.

In the layout example illustrated in FIG. 4, the transistors TGL, FDG, and RST are formed in an active region 41. The transistor FCG is formed in an active region 42, and the transistor AMP is formed in an active region 43. It is to be noted that in the example illustrated in FIG. 4, the capacitive element 25 includes a MIM capacitor. Furthermore, each pixel P of the imaging device 1 is provided with a separation section 55 and an oxide film 56 as illustrated in FIG. 4.

The separation section 55 is provided between adjacent photoelectric converters, and separates the photoelectric converters. For example, the separation sections 55 are provided between the respective first photoelectric converters 12 of adjacent pixels P and between the first photoelectric converter 12 and the second photoelectric converter 22. A portion of the separation section 55 is formed at a boundary between the adjacent pixels P. As illustrated in FIG. 4, the oxide film 56 is formed around each transistor of the pixel P. The oxide film 56 includes, for example, a silicone oxide film, a silicon nitride film, or the like, and may be said to be a separation section that separates elements.

The vertical drive unit 111 controls a signal such as a signal STGL, a signal SFDG, a signal SFCG, or a signal SRST input to each pixel P, thereby causing the transistor AMP of the pixel P to output a signal to the vertical signal line VSL. For example, the vertical drive unit 111 is configured to read out a signal based on an electric charge into which light has been photoelectrically converted by the first photoelectric converter 12, a signal based on an electric charge into which light has been photoelectrically converted by the second photoelectric converter 22, and a signal based on the electric charges into which light has been photoelectrically converted by the first and second photoelectric converters 12 and 22.

For example, the imaging device 1 may transfer an electric charge converted by the first photoelectric converter 12 to the first FD1 and read out a signal according to the electric charge converted by the first photoelectric converter 12. Furthermore, for example, the imaging device 1 may transfer an electric charge converted by the first photoelectric converter 12 and an electric charge converted by the second photoelectric converter 22 to the first FD1 and the second FD2 and read out a signal according to an electric charge obtained by adding the electric charge converted by the first photoelectric converter 12 and the electric charge converted by the second photoelectric converter 22.

As described above, the imaging device 1 according to the present embodiment includes the second photoelectric converter 22 having a low sensibility; therefore, even in an imaging condition in which an electric charge of the first photoelectric converter 12 is saturated, it is possible to generate a signal of a pixel according to an amount of light that has entered. Thus, it is possible to expand the dynamic range. Furthermore, the imaging device 1 includes the capacitive element 25 that accumulates an electric charge overflowed from the second photoelectric converter 22; therefore, it is possible to obtain a signal according to an electric charge obtained by adding an electric charge accumulated in the second photoelectric converter 22 and an electric charge accumulated in the capacitive element 25. Thus, even in a case where the second photoelectric converter 22 is saturated, it is possible to generate a signal of a pixel according to an amount of incident light. Accordingly, it is possible to make the dynamic range wider.

Furthermore, in the present embodiment, as described above, the high-level or low-level power supply voltage VDD1 is selectively supplied to the power supply line coupled to the transistor RST of a pixel P. In a period in which readout of a signal of a pixel P is not performed, for example, a period after readout of a signal from a pixel P, the low-level power supply voltage VDD1 is provided to the power supply line coupled to the transistor RST of that pixel P. A low voltage is supplied to the first FD1 through the transistor RST, thereby a low voltage is applied to the gate of the transistor AMP, which makes it possible to put the transistor AMP into an off-state. The low-level power supply voltage VDD1 is assumed to be a low voltage that allows the transistor AMP to go into the off-state.

In the example illustrated in FIG. 3, the first FD1, the second FD2, and the power supply line are electrically coupled through the transistors RST and FDG; thus, it is possible to supply the low-level power supply voltage VDD1 to the first FD1 and the second FD2. Depending on the input low-level power supply voltage VDD1, the transistors RST and FDG supply a low voltage to the first FD1. The low voltage is held in the first FD1, thereby it becomes possible to put the transistor AMP of a pixel P into the off-state and put that pixel P into an unselected state. Thus, it is possible for the imaging device 1 to sequentially read out a signal of a pixel from pixels P in a selected row, i.e., a pixel row to be read out into the vertical signal line VSL while putting the transistors AMP of pixels P in unselected rows in the off-state.

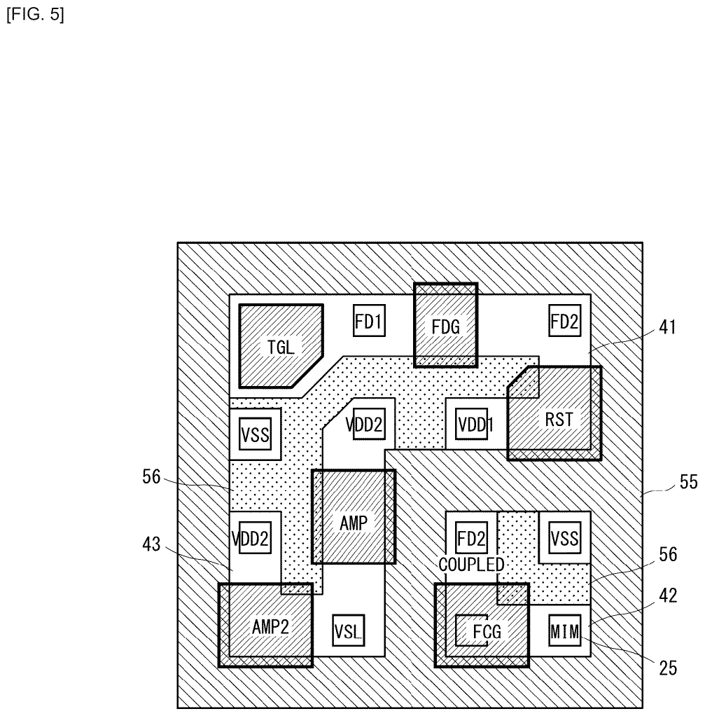

In this way, the imaging device 1 performs on-off control of the transistor AMP by the voltage supply to the first FD1 of each pixel P, which makes it possible to make a selection of a pixel. Thus, it is possible to configure the pixel P not to include a selection transistor for making a selection of a pixel. As compared with a case where a selection transistor is provided separately, it is possible to reduce the number of elements disposed in the pixel P, and therefore is possible to make the gate area of the transistor AMP sufficiently large as in the example illustrated in FIG. 4. It is to be noted that a plurality of amplifier transistors coupled in parallel to one another may be provided. For example, as in an example illustrated in FIG. 5, the transistor AMP and a transistor AMP2 coupled in parallel to the transistor AMP may be disposed.

In the imaging device 1 according to the present embodiment, it is possible to reduce random noise by the maximization of the size of the transistor AMP. Thus, it is possible to generate a less-noise signal of a pixel and achieve a wide dynamic range. It is possible to expand the low-illumination-side dynamic range.

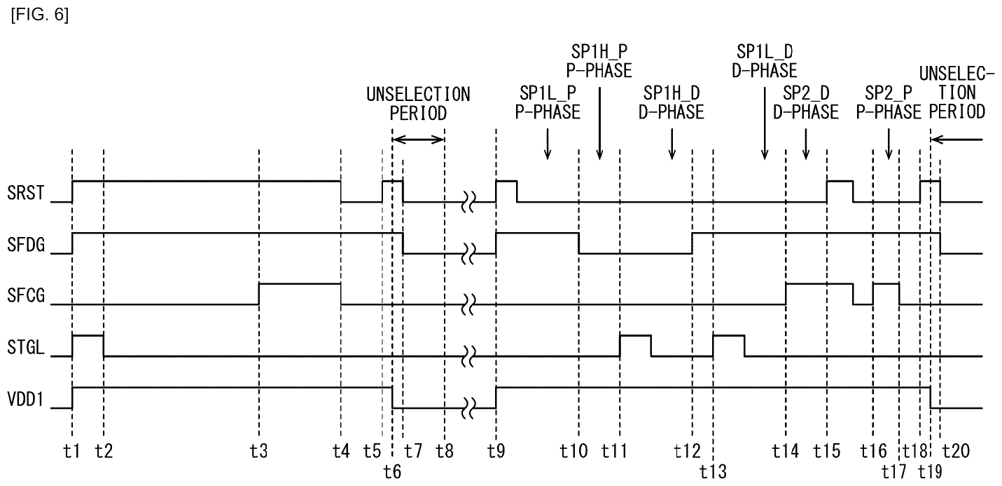

FIG. 6 is a timing chart illustrating an example of the operation of the imaging device according to the first embodiment. The timing chart illustrated in FIG. 6 illustrates drive signals (a signal SRST, a signal SFDG, a signal SFCG, and a signal STGL) and the power supply voltage VDD1 that are supplied to a pixel P of the imaging device; the horizontal axis of the timing chart indicates the time. In FIG. 6, a transistor to which a high-level drive signal has been input goes into an on-state, and a transistor to which a low-level drive signal has been input goes into an off-state.

At time t1, the signals SRST, SFDG, and STGL and the power supply voltage VDD1 have become at high level. The signals SRST, SFDG, and STGL have become at high level, thereby the transistors RST, FDG, and TGL go into the on-state. The second FD2, the first FD1, and the first photoelectric converter 12 are electrically coupled to the power supply line supplied with the high-level power supply voltage VDD1. Thus, electric charges in the second FD2, the first FD1, and the first photoelectric converter 12 are discharged, and voltages of the first FD1, the second FD2, and the first photoelectric converter 12 are reset.

At time t2, the signal STGL has become at low level, thereby the transistor TGL goes into the off-state, and the first photoelectric converter 12 and the first FD are electrically decoupled. The first photoelectric converter 12 photoelectrically converts light that has entered, and accumulates a generated electric charge.

At time t3, the signal SFCG has become at high level, thereby the transistor FCG goes into the on-state, and the capacitive element 25 and the second photoelectric converter 22 are electrically coupled to the power supply line provided with the high-level power supply voltage VDD1. Thus, electric charges in the capacitive element 25 and the second photoelectric converter 22 are discharged, and voltages of the capacitive element 25 and the second photoelectric converter 22 are reset.

At time t4, the signals SRST and SFCG have become at low level, thereby the capacitive element 25 and the second photoelectric converter 22 are electrically decoupled from the second FD2. The second photoelectric converter 22 photoelectrically converts light that has entered, and accumulates a generated electric charge. If an overflow occurs, the capacitive element 25 accumulates an electric charge overflowed from the second photoelectric converter 22.

At time t5, the signal SRST has become at high level, thereby the transistor RST goes into the on-state. Furthermore, the signal SFDG is at high level, and the transistor FDG is in the on-state; thus, the second FD2 and the first FD1 are electrically coupled to the power supply line provided with the power supply voltage VDD1. At time t6, the power supply voltage VDD1 has become at low level, and the low-level power supply voltage VDD1 is provided to the second FD2 and the first FD1. The first FD1 goes into a state where it has been supplied with the low-level power supply voltage VDD1.

At time t7, the signals SRST and SFDG have become at low level, thereby the transistors RST and FDG go into the off-state. The power supply line provided with the power supply voltage VDD1, the second FD2, and the first FD1 are electrically separated, and the low-level power supply voltage VDD1 is held in the first FD1. In this case, for example, a low voltage according to the low-level power supply voltage VDD1 supplied from the power supply line is held in the first FD1, and is input to the gate of the transistor AMP, thereby that transistor AMP goes into the off-state. The pixel P whose transistor AMP has been put into the off-state goes into an unselected state, and a period from the time t6 to time t8 becomes an unselection period. It is to be noted that in a period after the time t8, the transistors AMP of pixels P in unselected rows are in the off-state, and signals are sequentially read out from pixels P in a selected row.

At time t9, the signals SRST and SFDG and the power supply voltage VDD1 have become at high level. The signals SRST and SFDG have become at high level, thereby the power supply line supplied with the high-level power supply voltage VDD1, the second FD2, and the first FD1 are electrically coupled. Thus, electric charges in the second FD2 and the first FD1 are discharged, and voltages of the second FD2 and the first FD1 are reset.

In a P-phase (pre-charge phase) period after the voltages of the first FD1 and the second FD2 have been reset, a signal according to voltages of the first FD1 and the second FD2 after the reset is output, as a signal SP1L_P, to the vertical signal line VSL by the transistor AMP. The signal SP1L_P may be said to be a signal indicating a reset level (a reference level) of the first FD1 and the second FD2 in a case where the first FD1 and the second FD2 are electrically coupled. In the example illustrated in FIG. 6, the signal SP1L_P output to the vertical signal line VSL in a period from the time t9 to time t10 is converted into a digital signal by AD conversion in the signal processing unit 112 (see FIG. 2).

Furthermore, at the time t10, the signal SFDG has become at low level, thereby the transistor FDG goes into the off-state, and the first FD1 and the second FD2 are electrically decoupled. Thus, a signal according to a voltage of the first FD1 after the reset is output, as a signal SP1H_P, to the vertical signal line VSL by the transistor AMP. The signal SP1H_P may be said to be a signal indicating a reset level (a reference level) of the first FD1 in a case where the first FD1 and the second FD2 are electrically decoupled. In the example illustrated in FIG. 6, the signal SP1H_P output to the vertical signal line VSL in a period from the time t10 to time t11 is converted into a digital signal by AD conversion in the signal processing unit 112.

At the time t11, the signal STGL has become at high level, thereby the transistor TGL goes into the on-state, and the first photoelectric converter 12 and the first FD1 are electrically coupled. Thus, an electric charge into which light has been photoelectrically converted and accumulated by the first photoelectric converter 12 is transferred to the first FD1. In a D-phase (data phase) period after the electric charge has been transferred to the first FD1, a signal according to a voltage of the first FD1 after the charge transfer is output, as a signal SP1H_D, to the vertical signal line VSL by the transistor AMP. The signal SP1H_D is a signal according to the electric charge transferred from the first photoelectric converter 12 in a state where the first FD1 and the second FD2 are electrically decoupled. In the example illustrated in FIG. 6, the signal SP1H_D output to the vertical signal line VSL in a period from the time t11 to time t12 is converted into a digital signal by AD conversion in the signal processing unit 112.

Furthermore, at the time t12, the signal SFDG has become at high level, thereby the transistor FDG goes into the on-state, and the first FD1 and the second FD2 are electrically coupled. Moreover, at time t13, the signal STGL has become at high level, and the transistor TGL goes into the on-state. Thus, an electric charge into which light has been photoelectrically converted by the first photoelectric converter 12 is transferred and accumulated in the first FD1 and the second FD2. The electric charge generated by the first photoelectric converter 12 is divided between the first FD1 and the second FD2. In this case, a signal according to voltages of the first FD1 and the second FD2 is output, as a signal SP1L_D, to the vertical signal line VSL by the transistor AMP. The signal SP1L_D is a signal according to the electric charge transferred from the first photoelectric converter 12 in a state where the first FD1 and the second FD2 are electrically coupled. In the example illustrated in FIG. 6, the signal SP1L_D output to the vertical signal line VSL in a period from the time t13 to time t14 is converted into a digital signal by AD conversion in the signal processing unit 112.

At the time t14, the signal SFCG has become at high level, thereby the transistor FCG goes into the on-state. Furthermore, the signal SFDG is at high level, and the transistor FDG is in the on-state; thus, the second photoelectric converter 22, the capacitive element 25, the second FD2, and the first FD1 are electrically coupled to one another. Accordingly, the electric charge into which light has been photoelectrically converted by the second photoelectric converter 22 and accumulated in the second photoelectric converter 22 and the capacitive element 25 is transferred to the second FD2 and the first FD1. In this case, in the first FD1 and the second FD2, the respective electric charges generated by the first and second photoelectric converters 12 and 22 are added.

In a D-phase period after the charge transfer, the transistor AMP of the pixel P outputs, as a signal SP2_D, a signal according to voltages of the first FD1 and the second FD2, i.e., a signal based on an electric charge obtained by adding the electric charges into which light has been photoelectrically converted by the first and second photoelectric converters 12 and 22 to the vertical signal line VSL. In the example illustrated in FIG. 6, the signal SP2_D output to the vertical signal line VSL in a period from the time t14 to time t15 is converted into a digital signal by AD conversion in the signal processing unit 112.

At the time t15, the signal SRST has become at high level, thereby the second photoelectric converter 22, the capacitive element 25, the second FD2, and the first FD1 are electrically coupled to the power supply line supplied with the high-level power supply voltage VDD1. Thus, electric charges in the second photoelectric converter 22, the capacitive element 25, the second FD2, and the first FD1 are discharged, and voltages of the second photoelectric converter 22, the capacitive element 25, the second FD2, and the first FD1 are reset.

In a P-phase period after the reset, a signal according to voltages of the capacitive element 25, the first FD1, and the second FD2 after the reset is output, as a signal SP2_P, to the vertical signal line VSL by the transistor AMP. The signal SP2_P may be said to be a signal indicating a reset level in a case where the capacitive element 25, the first FD1, and the second FD2 are electrically coupled. In the example illustrated in FIG. 6, the signal SP2_P output to the vertical signal line VSL in a period from time t16 to time t17 is converted into a digital signal by AD conversion in the signal processing unit 112.

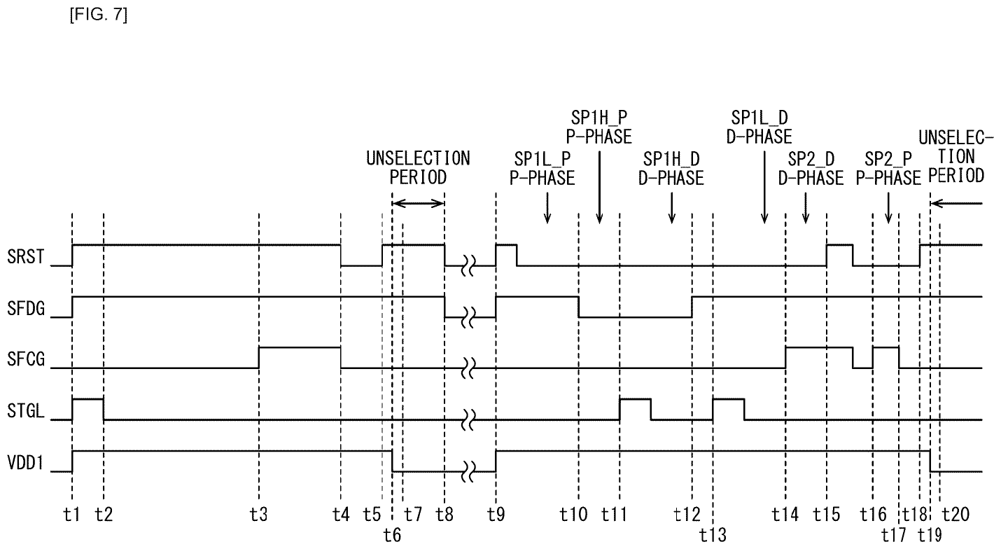

At time t18, the signal SRST has become at high level. From time t19 onward, it becomes an unselection period as with the case of the period from the time t6 to the time t8. After the readout of signals from pixels P in the selected row, in the pixels P in that selected row, the transistor AMP is put into the off-state by the supply of low voltage to the first FD1, and a process of reading out a signal from each pixel P in the next selected row is performed. It is to be noted that in a case of putting a pixel P into an unselected state, it may continue to supply the low-level power supply voltage VDD1 to the first FD1 and the gate of the transistor AMP of that pixel P through the transistors RST and FDG. In an example illustrated in FIG. 7, in the unselection period from the time t6 to the time t8 and the unselection period from the time t18 onward, the transistors RST and FDG remain in the on-state, and, when the low-level power supply voltage VDD1 has been input to the gate of the transistor AMP, the transistor AMP goes into the off-state.

The signal processing unit 112 performs, for example, signal processing such as correlated double sampling on a signal of a pixel that has been converted into a digital signal. As an example, the signal processing unit 112 calculates a difference between the signals SP1L_D and SP1L_P, and acquires the calculated difference as a pixel signal SP1L. The signal processing unit 112 calculates a difference between the signals SP1H_D and SP1H_P, and acquires the calculated difference as a pixel signal SP1H. Furthermore, the signal processing unit 112 acquires a difference between the signals SP2_D and SP2_P as a pixel signal SP2. The signal processing unit 112 outputs the processed pixel signals (for example, the pixel signals SP1L, SP1H, and SP2, etc.) to the output unit 114 through the horizontal signal line 121. The output unit 114 sequentially outputs the input pixel signals to the processing unit 103.

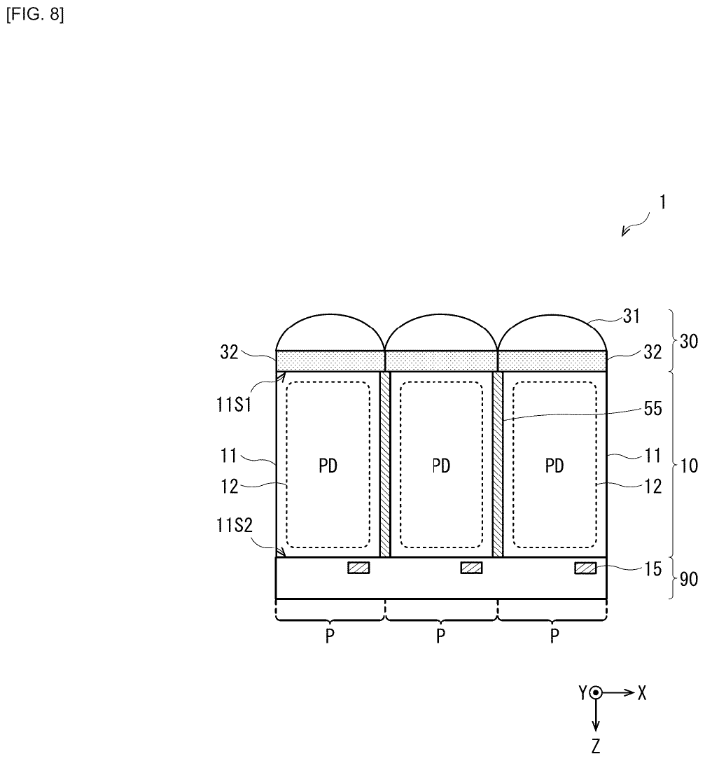

FIG. 8 is a diagram illustrating an example of a cross-sectional configuration of the imaging device according to the first embodiment. The imaging device 1 has a configuration in which a light receiving unit 10, a light guiding unit 30, and a multi-layer wiring layer 90 are stacked. The light receiving unit 10 includes the semiconductor substrate 11 having first and second surfaces 11S1 and 11S2 opposed to each other. The light guiding unit 30 is provided on the first surface 11S1 side of the semiconductor substrate 11, and the multi-layer wiring layer 90 is provided on the second surface 11S2 side of the semiconductor substrate 11. It may be said that the light guiding unit 30 is provided on the side from which light from the optical system 101 (see FIG. 1) enters, and the multi-layer wiring layer 90 is provided on the side opposite to the side from which light enters. The imaging device 1 is a so-called back-illuminated imaging device.

The semiconductor substrate 11 includes, for example, a silicon substrate. The first photoelectric converter 12 is a photodiode (PD), and has a p-n junction in a predetermined region of the semiconductor substrate 11. The semiconductor substrate 11 is embedded with a plurality of the first photoelectric converters 12 and a plurality of the second photoelectric converters 22 (not illustrated). In the light receiving unit 10, the plurality of first photoelectric converters 12 and the plurality of second photoelectric converters 22 are provided along the first and second surfaces 11S1 and 11S2 of the semiconductor substrate 11.

The multi-layer wiring layer 90 has, for example, a configuration in which multiple wiring layers are stacked with an interlayer insulating layer inserted between them. The wiring layers of the multi-layer wiring layer 90 are formed, for example, using a material such as aluminum (Al), copper (Cu), or tungsten (W). Besides these, the wiring layers may be formed using polysilicon (poly-Si). The interlayer insulating layer is formed of, for example, a single-layer film including, of materials such as silicon oxide (SiOₓ), silicon nitride (SiNₓ), and silicon oxynitride (SiOₓN_{y}), one, or a multi-layered film including two or more of these materials.

In the semiconductor substrate 11 and the multi-layer wiring layer 90, the above-described transistors and the capacitive element 25 of the pixel P are formed. In FIG. 8, a gate electrode 15 of the transistor TGL is illustrated. Furthermore, F for example, the vertical drive unit 111, the signal processing unit 112, the horizontal drive unit 113, the output unit 114, the imaging control unit 115, the input-output terminal 116, etc. described above are formed in the semiconductor substrate 11 and the multi-layer wiring layer 90.

The light guiding unit 30 includes a lens unit 31 and a color filter 32, and guides light entering from above in FIG. 8 to the light receiving unit 10 side. The lens unit 31 is an optical member called an on-chip lens, and is provided above the color filter 32, one for each pixel P or one for several pixels P. Light from a subject enters the lens unit 31 through the optical system 101. The light guiding unit 30 is stacked on the light receiving unit 10 in a thickness direction perpendicular to the first surface 11S1 of the semiconductor substrate 11.

The separation section 55 is provided at a boundary between adjacent pixels P, and separates the pixels P. The separation section 55 has a trench structure provided at the boundary between the adjacent pixels P, and may be said to be a pixel separation section or a pixel separation wall. As illustrated in FIG. 8, the separation section 55 may be formed to extend to the second surface 11S2 of the semiconductor substrate 11. In the example illustrated in FIG. 8, the separation section 55 is provided to go through the semiconductor substrate 11.

It is to be noted that the imaging device 1 may include an antireflection film and a fixed charge film between the color filter 32 and the first photoelectric converter 12. The fixed charge film is a film having a fixed charge, and suppresses the occurrence of a dark current at an interface of the semiconductor substrate 11. The light guiding unit 30 may include an antireflection film and a fixed charge film.

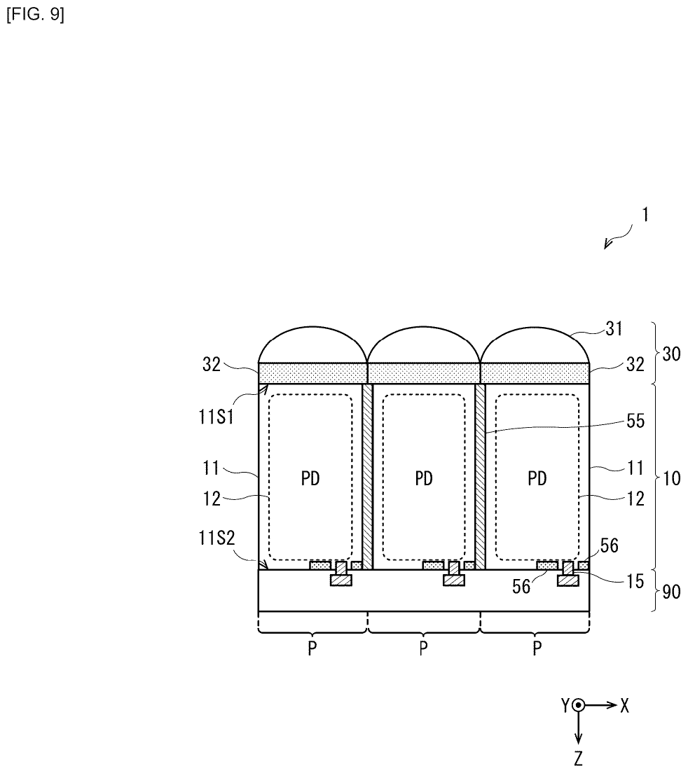

FIG. 9 is a diagram illustrating another example of the cross-sectional configuration of the imaging device according to the first embodiment. As illustrated in FIG. 9, the transistor TGL may be formed by digging in the semiconductor substrate 11. In the example illustrated in FIG. 9, a portion of the gate electrode 15 of the transistor TGL is formed adjacent to the first photoelectric converter 12 within the semiconductor substrate 11. Furthermore, in the semiconductor substrate 11, the oxide film 56 may be provided to surround the gate electrode 15 of the transistor TGL as illustrated in FIG. 9.

### [Action and Effect]

The imaging device 1 according to the present embodiment includes: a plurality of pixels (pixels P) each including a first photoelectric converter (the first photoelectric converter 12) configured to generate an electric charge by photoelectric conversion, an accumulation unit (the first FD1) configured to accumulate the electric charge into which light has been photoelectrically converted, a capacitive element (the capacitive element 25) configured to accumulate an overflowed electric charge, a first transistor (the transistor FCG) provided between the capacitive element and the accumulation unit, and a second transistor (the transistor AMP) configured to output a signal based on the electric charge accumulated in the accumulation unit; and a signal line (the vertical signal line VSL) coupled to second transistors of the plurality of pixels. The pixels include a second photoelectric converter (the second photoelectric converter 22) configured to generate an electric charge by photoelectric conversion. The capacitive element is configured to accumulate an electric charge overflowed from the second photoelectric converter.

A pixel P of the imaging device 1 according to the present embodiment is provided with the first photoelectric converter 12, the second photoelectric converter 22, and the capacitive element 25 configured to accumulate an electric charge overflowed from the second photoelectric converter 22. Thus, it is possible to obtain a signal of a pixel according to an amount of incident light, and is possible to expand the dynamic range.

Furthermore, in the imaging device 1, a selection of a pixel is made by control of the transistor AMP. Thus, it is possible to reduce the number of elements disposed in a pixel P, and therefore is possible to increase the size of the transistor AMP sufficiently. It is possible to suppress noise mixed in a signal of a pixel and improve the dynamic range.

Subsequently, modification examples of the present disclosure are described. In the following, a similar component to the above-described embodiment is assigned the same reference numeral, and its description is omitted accordingly.

### 1-1. Modification Example 1

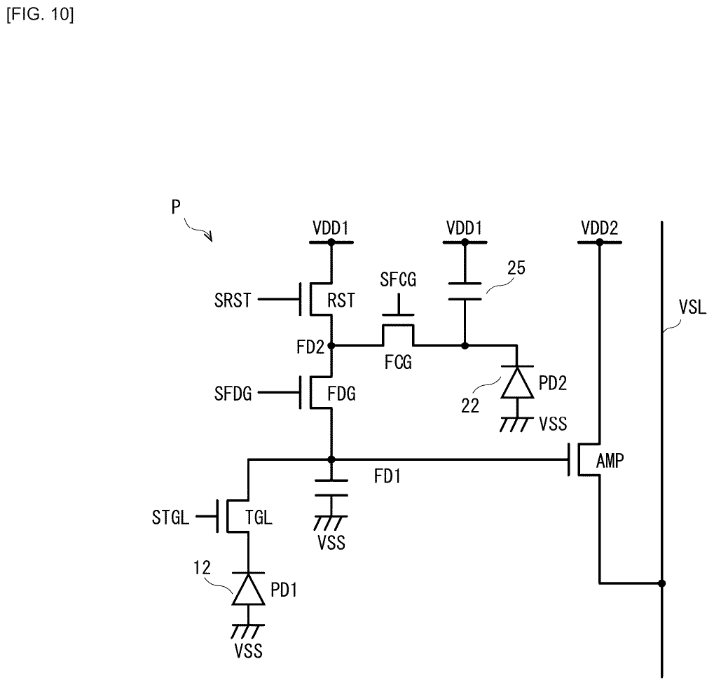

FIG. 10 is a diagram illustrating an example of a circuit configuration of a pixel of an imaging device according to Modification Example 1 of the present disclosure. One of electrodes of the capacitive element 25 is electrically coupled to the second photoelectric converter 22. The other electrode of the capacitive element 25 and the transistor RST are electrically coupled to a shared power supply line, and are selectively provided with the high-level or low-level power supply voltage VDD1.

In the example illustrated in FIG. 10, the capacitive element 25 may accumulate an electric charge in a state where it has been supplied with the low-level power supply voltage VDD1. In this case, it is possible to adjust the value of the low-level power supply voltage VDD1 in consideration of a saturated charge amount of the capacitive element 25 and a dark current, and it is possible to suppress a decrease in the saturated charge amount and an increase in dark current.

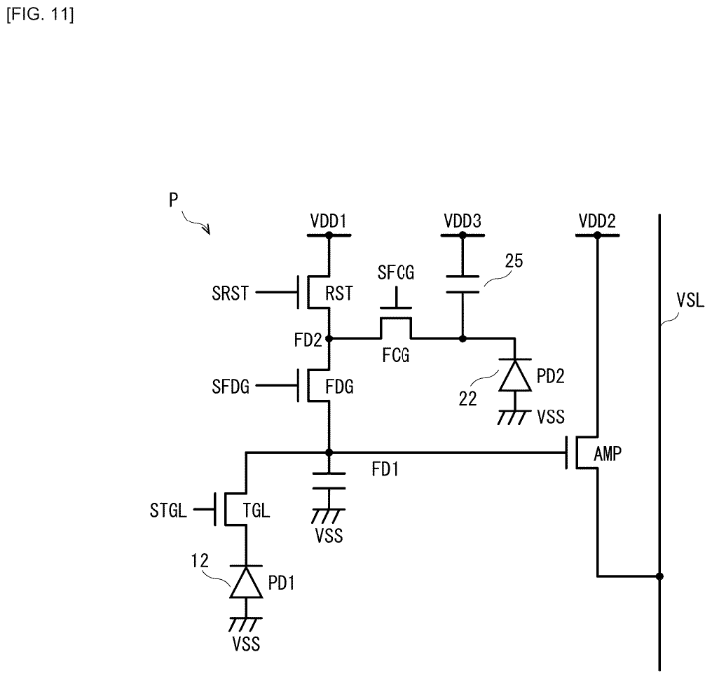

It is to be noted that the other electrode of the capacitive element 25 may be coupled to a different power supply line from the power supply line coupled to the transistor RST as in an example illustrated in FIG. 11. In the example illustrated in FIG. 11, the other electrode of the capacitive element 25 is electrically coupled to a power supply line and voltage source from which a power supply voltage VDD3 is supplied. Also in this case, it is possible to determine the value of the power supply voltage VDD3 in consideration of the saturated charge amount and a dark current, and it is possible to suppress a decrease in the saturated charge amount and an increase in dark current.

### 1-2. Modification Example 2

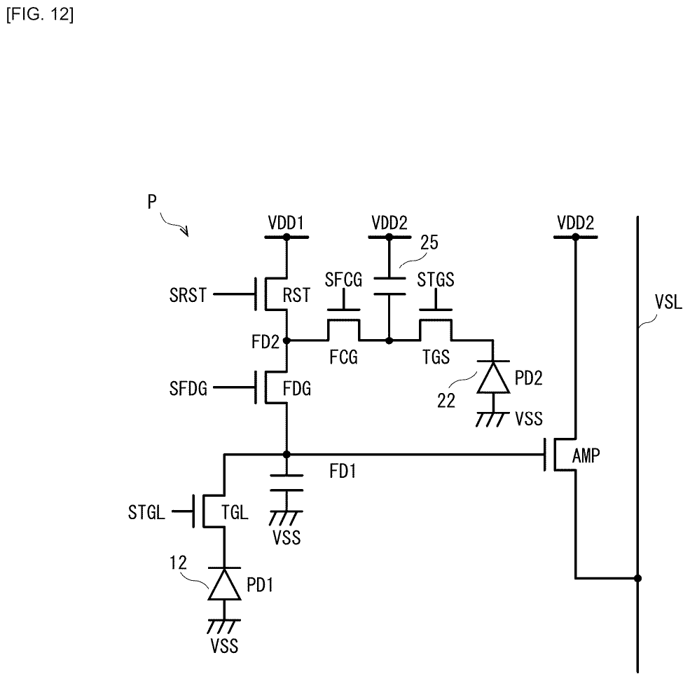

FIG. 12 is a diagram illustrating an example of a circuit configuration of a pixel of an imaging device according to Modification Example 2. In a pixel P of the imaging device 1, as illustrated in FIG. 12, a transistor TGS may be provided between the second photoelectric converter 22 and the capacitive element 25. The transistor TGS is configured to couple the second photoelectric converter 22 and the capacitive element 25.

As illustrated in FIG. 12, the transistor TGS is controlled by a signal STGS, and electrically couples or decouples the second photoelectric converter 22 and the capacitive element 25. The transistor TGS is controlled to be on/off by the signal STGS, and may electrically couple the side of the second photoelectric converter 22 and the side of the capacitive element 25 and the transistor FCG. By controlling a threshold of the transistor TGS, a signal level of the signal STGS, etc., it becomes possible to control the movement of an electric charge from the second photoelectric converter 22 to the capacitive element 25.

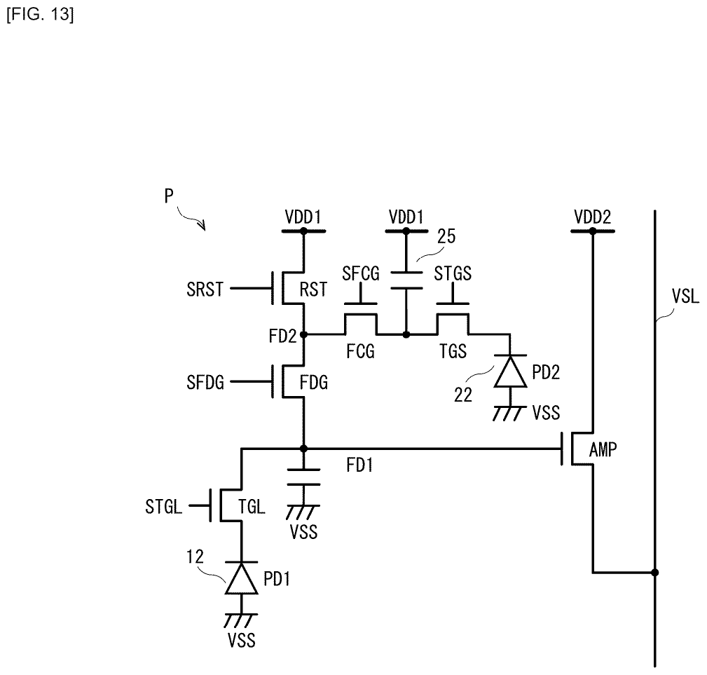

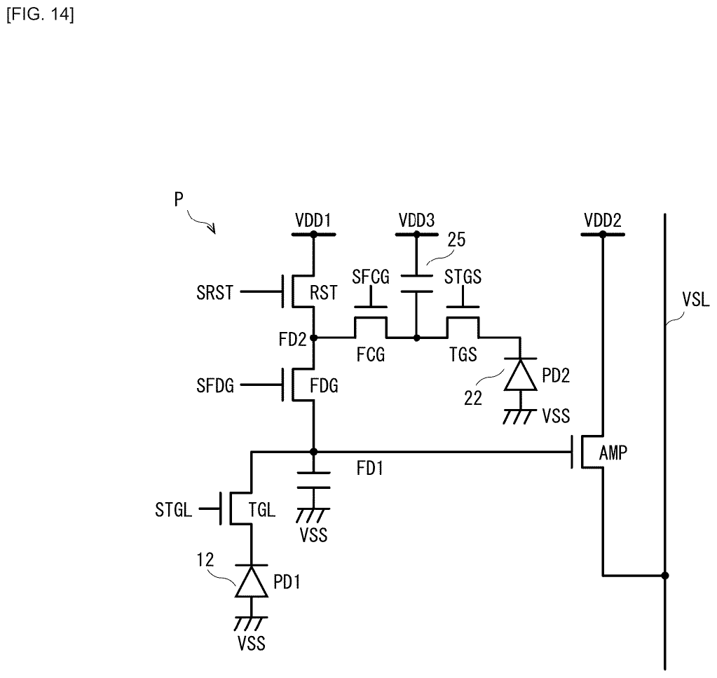

It is to be noted that the capacitive element 25 and the transistor RST may be electrically coupled to a shared power supply line, or may be electrically coupled to different power supply lines from each other as with the case of the above-described modification example. For example, as illustrated in FIG. 13, the other electrode of the capacitive element 25 may be electrically coupled to the power supply line and voltage source from which the power supply voltage VDD1 is supplied. Furthermore, for example, as illustrated in FIG. 14, the other electrode of the capacitive element 25 may be electrically coupled to the power supply line and voltage source from which the power supply voltage VDD3 is supplied.

### 2. Second Embodiment

Subsequently, a second embodiment of the present disclosure is described. In the following, a similar component to the above-described embodiment is assigned the same reference numeral, and its description is omitted accordingly.

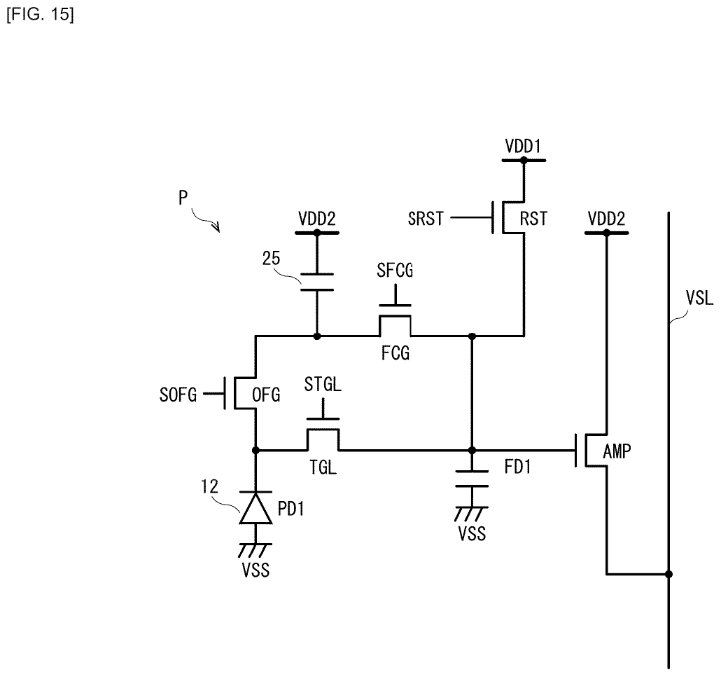

FIG. 15 is a diagram illustrating an example of a circuit configuration of a pixel of an imaging device according to the second embodiment. A pixel P includes the first photoelectric converter 12, the transistor TGL, the first FD1, the transistor AMP, the transistor RST, the capacitive element 25, and the transistor FCG. Furthermore, in the present embodiment, the pixel P includes a transistor OFG.

The transistor OFG is configured to couple the first photoelectric converter 12 and the capacitive element 25. As illustrated in FIG. 15, the transistor OFG is controlled by a signal SOFG, and electrically couples or decouples the first photoelectric converter 12 and the capacitive element 25. The transistor OFG is controlled to be on/off by the signal SOFG, and may electrically couple the first photoelectric converter 12 side and the capacitive element 25 side. By controlling a threshold of the transistor OFG, a signal level of the signal SOFG, etc., it becomes possible to control the movement of an electric charge from the first photoelectric converter 12 to the capacitive element 25.

The capacitive element 25 is configured to accumulate an electric charge overflowed from the first photoelectric converter 12. In the example illustrated in FIG. 15, one of electrodes of the capacitive element 25 is electrically coupled to the first photoelectric converter 12 through the transistor OFG. Furthermore, the other electrode of the capacitive element 25 is coupled to the power supply line supplied with the power supply voltage VDD2. The capacitive element 25 may hold the electric charge overflowed from the first photoelectric converter 12.

The pixel P is provided with the capacitive element 25; thus, even in a case of the occurrence of an electric charge exceeding a saturated charge amount of the first photoelectric converter 12, it is possible to accumulate an electric charge overflowed from the first photoelectric converter 12 in the capacitive element 25. Therefore, it is possible to obtain a signal according to an electric charge obtained by adding the electric charge accumulated in the first photoelectric converter 12 and the electric charge accumulated in the capacitive element 25.

The transistor FCG is configured to couple the capacitive element 25 and the first FD1. As illustrated in FIG. 15, the transistor FCG is controlled by a signal SFCG, and electrically couples or decouples the capacitive element 25 and the first FD1. The transistor FCG is controlled to be on/off by the signal SFCG, and electrically couples or decouples the capacitive element 25 and the first FD1. The transistor FCG may transfer an electric charge accumulated in the capacitive element 25 to the first FD1.

The vertical drive unit 111 (see FIG. 2) controls a signal such as a signal STGL, a signal SFCG, a signal SRST, or a signal SOFG input to each pixel P, thereby causing the transistor AMP of the pixel P to output a signal to the vertical signal line VSL. For example, the imaging device 1 may transfer an electric charge converted by the first photoelectric converter 12 to the first FD1 and read out a signal according to the electric charge converted by the first photoelectric converter 12. Furthermore, for example, the imaging device 1 may transfer an electric charge accumulated in the first photoelectric converter 12 and an electric charge accumulated in the capacitive element 25 to the first FD1 and read out a signal according to an electric charge obtained by adding the electric charge accumulated in the first photoelectric converter 12 and the electric charge accumulated in the capacitive element 25.

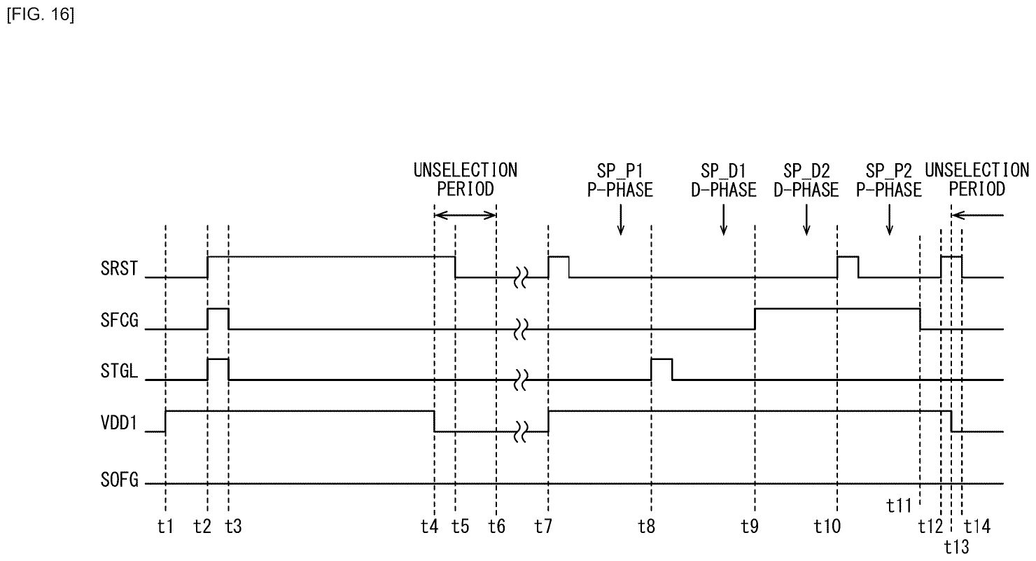

FIG. 16 is a timing chart illustrating an example of the operation of the imaging device according to the second embodiment. The timing chart illustrated in FIG. 16 illustrates drive signals (a signal SRST, a signal SFCG, a signal STGL, and a signal SOFG) and the power supply voltage VDD1 that are supplied to a pixel P of the imaging device; the horizontal axis of the timing chart indicates the time. In FIG. 16, a transistor to which a high-level drive signal has been input goes into an on-state, and a transistor to which a low-level drive signal has been input goes into an off-state. It is to be noted that in the example illustrated in FIG. 16, the voltage of the signal SOFG is assumed to be a fixed voltage (for example, at low level).

At time t1, the power supply voltage VDD1 has become at high level. Furthermore, at time t2, the signals SRST, SFCG, and STGL have become at high level. The signals SRST, SFCG, and STGL have become at high level, thereby the transistors RST, FCG, and TGL go into the on-state. The first FD1, the capacitive element 25, and the first photoelectric converter 12 are electrically coupled to the power supply line provided with the high-level power supply voltage VDD1. Thus, electric charges in the first FD1, the capacitive element 25, and the first photoelectric converter 12 are discharged, and voltages of the first FD1, the capacitive element 25, and the first photoelectric converter 12 are reset.

At time t3, the signals SFCG and STGL have become at low level, thereby the capacitive element 25 and the first photoelectric converter 12 are electrically decoupled from the first FD1. The first photoelectric converter 12 photoelectrically converts light that has entered, and accumulates a generated electric charge. If an overflow occurs, the capacitive element 25 accumulates an electric charge overflowed from the first photoelectric converter 12.

At time t4, the power supply voltage VDD1 has become at low level. In this case, the signal SRST is at high level, and the transistor RST is in the on-state; thus, the power supply line provided with the power supply voltage VDD1 and the first FD1 are electrically coupled, and the low-level power supply voltage VDD1 is provided to the first FD1. The first FD1 goes into a state where it has been supplied with the low-level power supply voltage VDD1.

At time t5, the signal SRST has become at low level, thereby the transistor RST goes into the off-state. The power supply line provided with the power supply voltage VDD1 and the first FD1 are electrically separated, and the first FD1 holds the low-level power supply voltage VDD1. The low-level power supply voltage VDD1 is input to the gate of the transistor AMP, and the transistor AMP goes into the off-state. The pixel P whose transistor AMP has been put into the off-state goes into an unselected state, and a period from the time t4 to time t6 becomes an unselection period. It is to be noted that in a period after the time t6, the transistors AMP of pixels P in unselected rows are in the off-state, and signals are sequentially read out from pixels P in a selected row.

At time t7, the signal SRST and the power supply voltage VDD1 have become at high level. The signal SRST has become at high level, thereby the power supply line supplied with the high-level power supply voltage VDD1 and the first FD1 are electrically coupled. Thus, an electric charge in the first FD1 is discharged, and a voltage of the first FD1 is reset.

In a P-phase period after the voltage of the first FD1 has been reset, a signal according to the first FD1 after the reset is output, as a signal SP_P1, to the vertical signal line VSL by the transistor AMP. The signal SP_P1 may be said to be a signal indicating a reset level (a reference level) of the first FD1. In the example illustrated in FIG. 16, the signal SP_P1 output to the vertical signal line VSL in a period from the time t7 to time t8 is converted into a digital signal by AD conversion in the signal processing unit 112 (see FIG. 2).

At the time t8, the signal STGL has become at high level, thereby the transistor TGL goes into the on-state, and the first photoelectric converter 12 and the first FD1 are electrically coupled. Thus, the electric charge into which light has been photoelectrically converted and accumulated in the first photoelectric converter 12 is transferred to the first FD1. In a D-phase period after the electric charge has been transferred to the first FD1, a signal according to a voltage of the first FD1 after the charge transfer is output, as a signal SP_D1, to the vertical signal line VSL by the transistor AMP. The signal SP_D1 is a signal according to the electric charge transferred from the first photoelectric converter 12. In the example illustrated in FIG. 16, the signal SP_D1 output to the vertical signal line VSL in a period from the time t8 to time t9 is converted into a digital signal by AD conversion in the signal processing unit 112.

At the time t9, the signal SFCG has become at high level, thereby the transistor FCG goes into the on-state, and the capacitive element 25 and the first FD1 are electrically coupled. Thus, the electric charge that has been overflowed from the first photoelectric converter 12 and accumulated in the capacitive element 25 is transferred to the first FD1. In this case, in the first FD1, the electric charge accumulated in the first photoelectric converter 12 and the electric charge accumulated in the capacitive element 25 are added.

In a D-phase period after the charge transfer, the transistor AMP of the pixel P outputs, as a signal SP_D2, a signal according to a voltage of the first FD1, i.e., a signal based on an electric charge obtained by adding the electric charges accumulated in the first photoelectric converter 12 and the capacitive element 25 to the vertical signal line VSL. In the example illustrated in FIG. 16, the signal SP_D2 output to the vertical signal line VSL in a period from the time t9 to time t10 is converted into a digital signal by AD conversion in the signal processing unit 112.

At the time t10, the signal SRST has become at high level, thereby the capacitive element 25 and the first FD1 are electrically coupled to the power supply line supplied with the high-level power supply voltage VDD1. Thus, electric charges in the capacitive element 25 and the first FD1 are discharged, and voltages of the capacitive element 25 and the first FD1 are reset.

In a P-phase period after the reset, a signal according to voltages of the capacitive element 25 and the first FD1 after the reset is output, as a signal SP_P2, to the vertical signal line VSL by the transistor AMP. The signal SP_P2 may be said to be a signal indicating a reset level in a case where the capacitive element 25 and the first FD1 are electrically coupled. In the example illustrated in FIG. 16, the signal SP_P2 output to the vertical signal line VSL in a period from the time t10 to time t11 is converted into a digital signal by AD conversion in the signal processing unit 112.

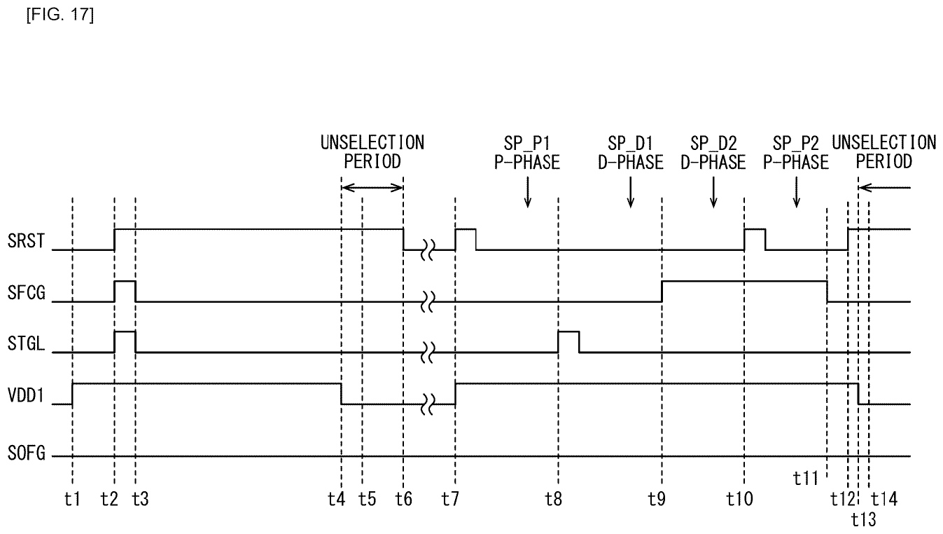

At time t12, the signal SRST has become at high level. From time t13 onward, it becomes an unselection period as with the case of the period from the time t4 to the time t6. After the readout of signals from the pixels P in the selected row, in the pixels P in that selected row, the transistor AMP is put into the off-state by the supply of low voltage to the first FD1, and a process of reading out a signal from each pixel P in the next selected row is performed. It is to be noted that in a case of putting a pixel P into an unselected state, it may continue to supply the low-level power supply voltage VDD1 to the first FD1 and the gate of the transistor AMP of that pixel P through the transistor RST. In an example illustrated in FIG. 17, in the unselection period from the time t4 to the time t6 and the unselection period from the time t13 onward, the transistor RST remains in the on-state, and the low-level power supply voltage VDD1 is input to the gate of the transistor AMP, thereby the transistor AMP goes into the off-state.

The signal processing unit 112 performs, for example, signal processing such as correlated double sampling on a signal of a pixel that has been converted into a digital signal. As an example, the signal processing unit 112 calculates a difference between the signals SP_D1 and SP_P1, and acquires the calculated difference as a pixel signal SP1. Furthermore, the signal processing unit 112 calculates a difference between the signals SP_D2 and SP_P2, and acquires the calculated difference as a pixel signal SP2. The signal processing unit 112 outputs the processed pixel signals to the output unit 114 through the horizontal signal line 121. The output unit 114 sequentially outputs the input pixel signals to the processing unit 103.

### [Action and Effect]

The imaging device 1 according to the present embodiment includes: a plurality of pixels (pixels P) each including a first photoelectric converter (the first photoelectric converter 12) configured to generate an electric charge by photoelectric conversion, an accumulation unit (the first FD1) configured to accumulate the electric charge into which light has been photoelectrically converted, a capacitive element (the capacitive element 25) configured to accumulate an overflowed electric charge, a first transistor (the transistor FCG) provided between the capacitive element and the accumulation unit, and a second transistor (the transistor AMP) configured to output a signal based on the electric charge accumulated in the accumulation unit; and a signal line (the vertical signal line VSL) coupled to second transistors of the plurality of pixels. The capacitive element is configured to accumulate an electric charge overflowed from the first photoelectric converter.

A pixel P of the imaging device 1 according to the present embodiment is provided with the first photoelectric converter 12 and the capacitive element 25 configured to accumulate an electric charge overflowed from the first photoelectric converter 12. Thus, it is possible to obtain a signal of a pixel according to an amount of incident light, and is possible to expand the dynamic range.

Furthermore, in the imaging device 1, a selection of a pixel is made by control of the transistor AMP. Thus, it is possible to reduce the number of elements disposed in a pixel P, and therefore is possible to increase the size of the transistor AMP sufficiently. It is possible to suppress noise mixed in a signal of a pixel and improve the dynamic range. Also in the present embodiment, it is possible to achieve similar effects to the first embodiment.

Subsequently, modification examples of the present disclosure are described. In the following, a similar component to the above-described embodiments is assigned the same reference numeral, and its description is omitted accordingly.

### 2-1. Modification Example 3

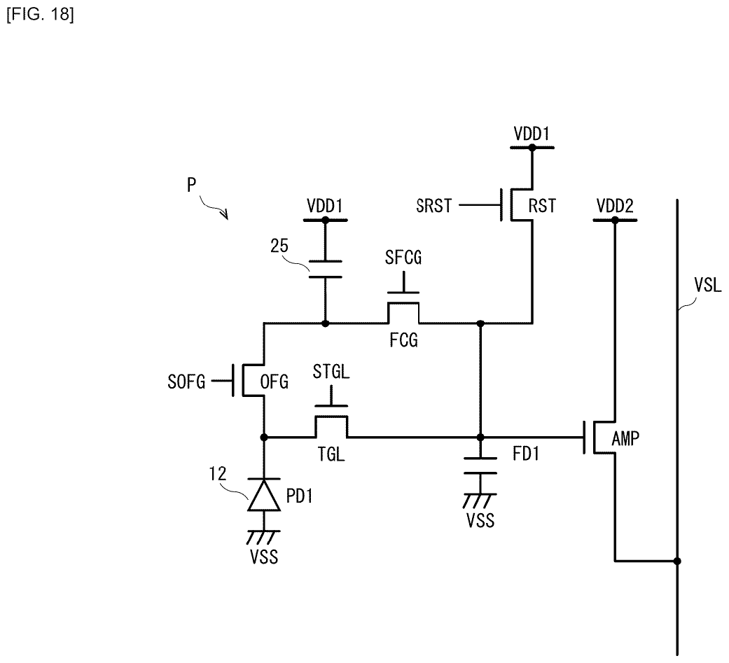

FIG. 18 is a diagram illustrating an example of a circuit configuration of a pixel of an imaging device according to Modification Example 3 of the present disclosure. One of electrodes of the capacitive element 25 is electrically coupled to the first photoelectric converter 12 through the transistor OFG. The other electrode of the capacitive element 25 and the transistor RST are electrically coupled to a shared power supply line, and are selectively provided with the high-level or low-level power supply voltage VDD1. In the example illustrated in FIG. 18, the capacitive element 25 may accumulate an electric charge in a state where it has been supplied with the low-level power supply voltage VDD1. In this case, it is possible to adjust the value of the low-level power supply voltage VDD1 in consideration of a saturated charge amount of the capacitive element 25 and a dark current, and it is possible to suppress a decrease in the saturated charge amount and an increase in dark current.

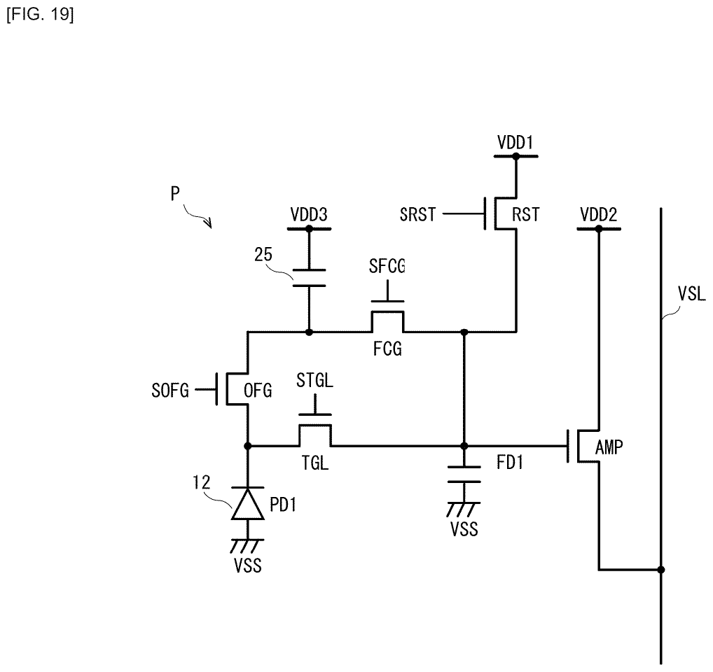

It is to be noted that the other electrode of the capacitive element 25 may be coupled to a different power supply line from the power supply line coupled to the transistor RST as in an example illustrated in FIG. 19. In the example illustrated in FIG. 19, the other electrode of the capacitive element 25 is electrically coupled to the power supply line and voltage source from which the power supply voltage VDD3 is supplied. Also in this case, it is possible to determine the value of the power supply voltage VDD3 in consideration of the saturated charge amount and a dark current, and it is possible to suppress a decrease in the saturated charge amount and an increase in dark current.

### 2-2. Modification Example 4

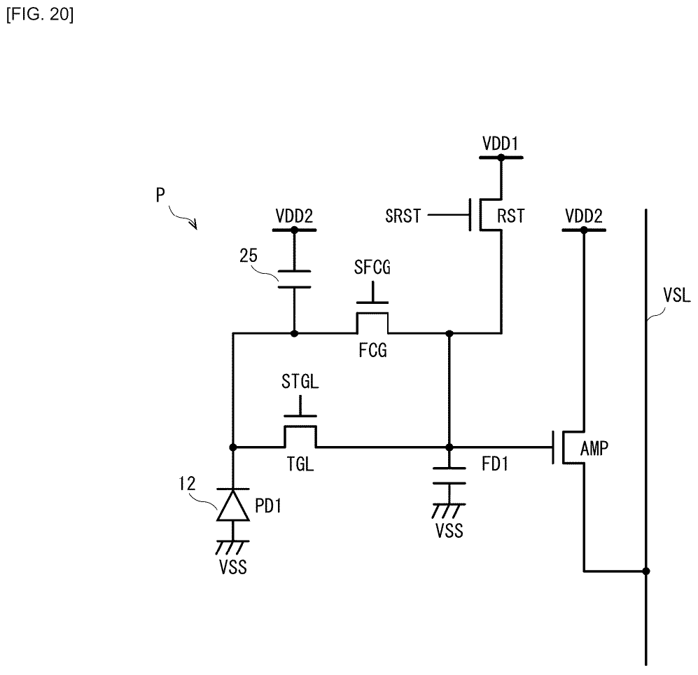

FIG. 20 is a diagram illustrating an example of a circuit configuration of a pixel of an imaging device according to Modification Example 4. The above-described transistor OFG does not have to be disposed between the first photoelectric converter 12 and the capacitive element 25. It is to be noted that also in the present modification example, the capacitive element 25 and the transistor RST may be electrically coupled to a shared power supply line, or may be electrically coupled to different power supply lines from each other.

### 2-3. Modification Example 5

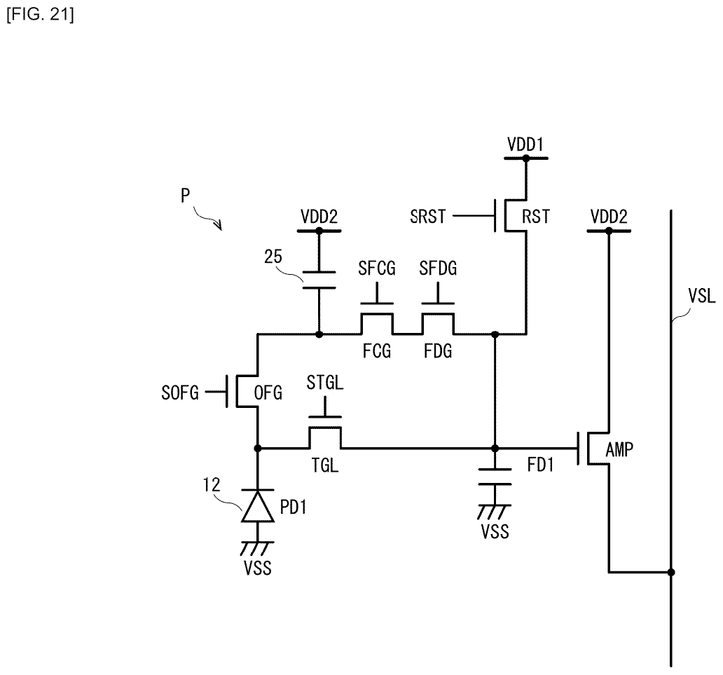

FIG. 21 is a diagram illustrating an example of a circuit configuration of a pixel of an imaging device according to Modification Example 5. In a pixel P of the imaging device 1, as illustrated in FIG. 21, the transistor FDG may be provided between the transistor FCG and the first FD1. The transistor FDG is configured to couple the transistor FCG and the first FD1.

As illustrated in FIG. 21, the transistor FDG is controlled by a signal SFDG, and electrically couples or decouples the transistor FCG and the first FD1. When the transistor FDG goes into the on-state, the capacitance added to the first FD1 becomes larger, which makes it possible to change the conversion efficiency of when an electric charge is converted into a voltage. The transistor FDG may be said to be a switching transistor that switches the capacitance coupled to the gate of the transistor AMP and changes the conversion efficiency.

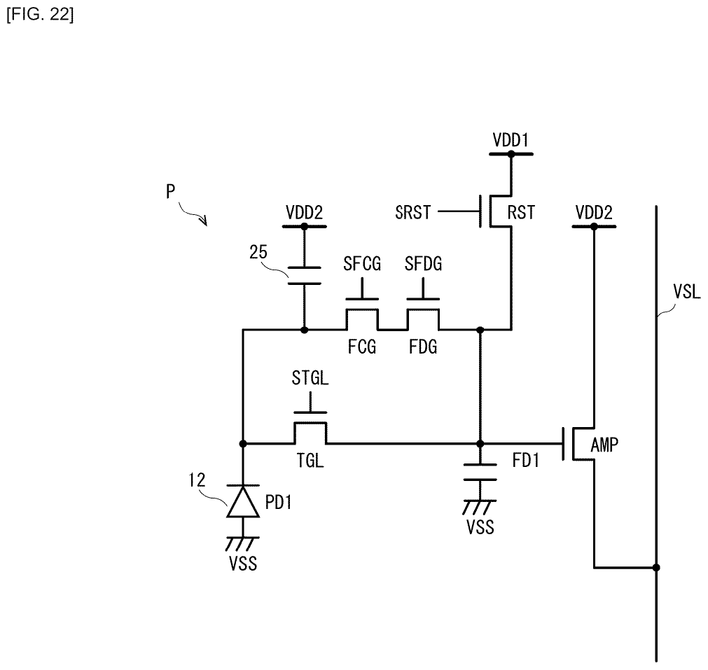

It is to be noted that also in the present modification example, the capacitive element 25 and the transistor RST may be electrically coupled to a shared power supply line, or may be electrically coupled to different power supply lines from each other. Furthermore, as illustrated in FIG. 22, the above-described transistor OFG does not have to be disposed between the first photoelectric converter 12 and the capacitive element 25.

### 2-4. Modification Example 6

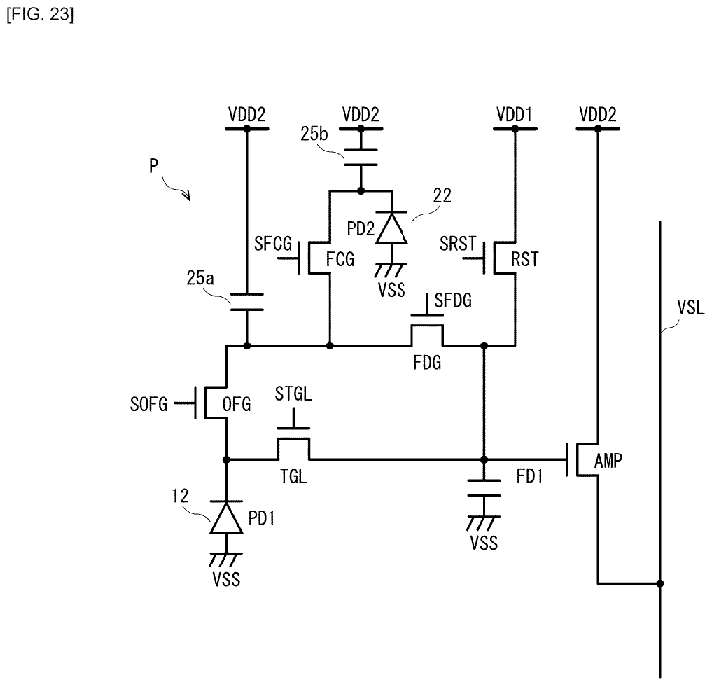

FIG. 23 is a diagram illustrating an example of a circuit configuration of a pixel of an imaging device according to Modification Example 6. In a pixel P of the imaging device 1, the second photoelectric converter 22 may be provided as illustrated in FIG. 23. For example, the first and second photoelectric converters 12 and 22 of the pixel P are configured to have different sensibilities to incoming light from each other. As an example, the sensibility of the second photoelectric converter 22 to light is lower than the sensibility of the first photoelectric converter 12 to light. The transistor FCG is configured to couple a capacitive element 25a and the transistor FDG.

Furthermore, each pixel P of the imaging device 1 includes two capacitive elements (capacitive elements 25a and 25b). The capacitive element 25a is configured to accumulate an electric charge overflowed from the first photoelectric converter 12. Furthermore, the capacitive element 25b is configured to accumulate an electric charge overflowed from the second photoelectric converter 22.

The pixel P of the imaging device 1 according to the present modification example is provided with the first photoelectric converter 12, the capacitive element 25a configured to accumulate an electric charge overflowed from the first photoelectric converter 12, the second photoelectric converter 22, and the capacitive element 25b configured to accumulate an electric charge overflowed from the second photoelectric converter 22. Thus, it is possible to obtain a signal of a pixel according to an amount of incident light, and is possible to expand the dynamic range.

It is to be noted that also in a case of the present modification example, the capacitive elements 25a and 25b and the transistor RST may be electrically coupled to a shared power supply line, or may be electrically coupled to different power supply lines from one another. Furthermore, the capacitive elements 25a and 25b may be electrically coupled to a shared power supply line, or may be electrically coupled to different power supply lines from each other.

### 3. Examples of Use

The imaging device 1 and the electronic apparatus 100 described above are available in, for example, as below, various cases of sensing light such as visible light, infrared light, ultraviolet light, or X-rays:
devices that take an image for appreciation, for example, a digital camera, a mobile device with a camera function, etc.
devices used for traffic, for example, an in-vehicle sensor that takes images of the front and rear, the surroundings, the inside, etc. of an automobile for the sake of safe driving such as automatic stop, recognition of a driver's condition, etc., a monitoring camera that monitors running vehicles and a road, a ranging sensor that measures a distance between vehicles or somethings, etc.
devices used in home electric appliances, such as a television, a refrigerator, and an air conditioner, and configured to capture a user's gesture to perform operation of an appliance in accordance with that gesture devices used for medical care and healthcare, for example, an endoscope, a device that performs angiography by means of infrared light reception, etc.
devices used for security, for example, a surveillance camera for crime prevention, a camera for person authentication, etc.
devices used for beauty, for example, a skin measuring instrument that takes an image of the skin, a microscope that takes an image of the scalp, etc.
devices used for sports, for example, an action camera or a wearable camera for sports use, etc.
devices used for agriculture, for example, a camera for monitoring the condition of a field or crops, etc.

### 4. Application Examples

### (Example of Application to Moving Body)

The technique according to the present disclosure (the present technology) is applicable to various products. For example, the technique according to the present disclosure may be realized as a device mounted on any of kinds of moving bodies such as a motor vehicle, an electric vehicle, a hybrid electric vehicle, a motorcycle, a bicycle, a personal transporter, an airplane, a drone, a vessel, and a robot.

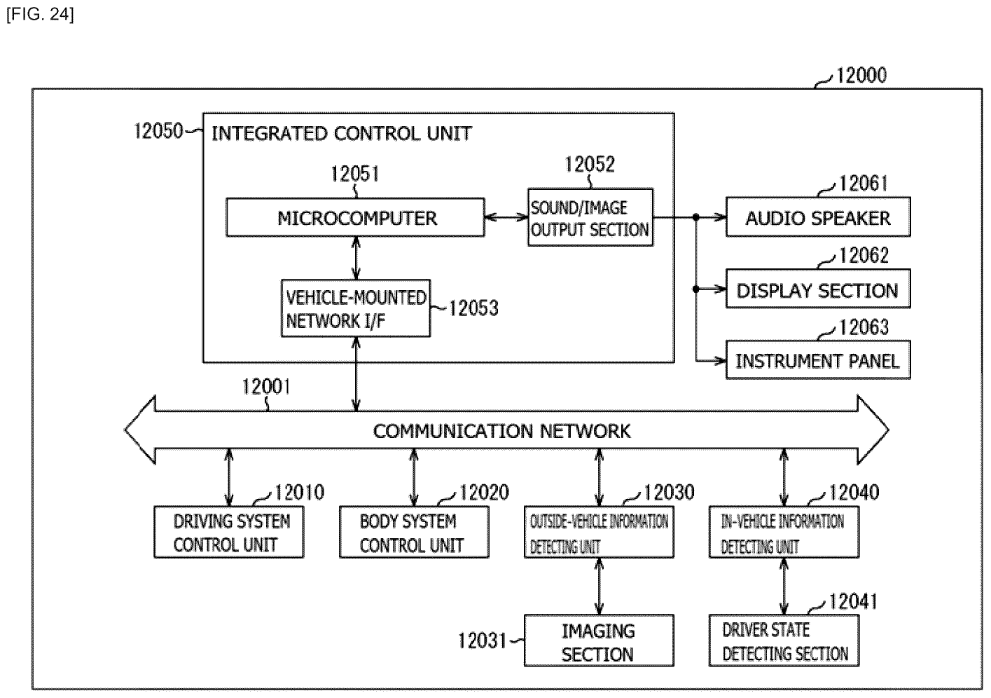

FIG. 24 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

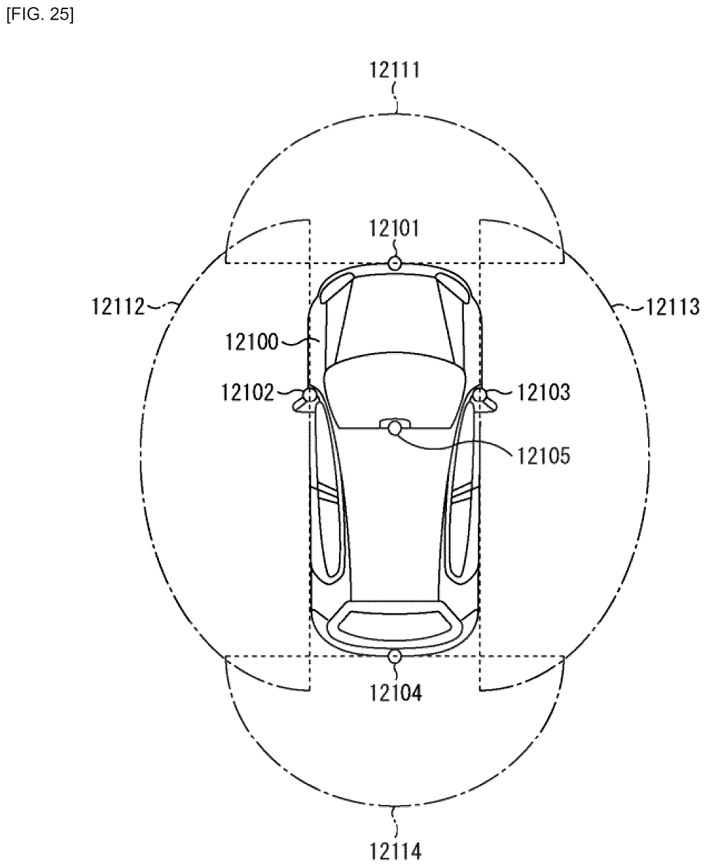

FIG. 25 is a diagram depicting an example of the installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 25 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As above, there has been described an example of the moving body control system to which the technique according to the present disclosure may be applied. The technique according to the present disclosure may be applied to, of the above-described components, for example, the imaging section 12031. Specifically, for example, the imaging device 1, the electronic apparatus 100, etc. are applicable to the imaging section 12031. By applying the technique according to the present disclosure to the imaging section 12031, it becomes possible to obtain a high-definition taken image; therefore, it is possible to perform high-precision control using the taken image in the moving body control system.

### (Example of Application to Endoscopic Surgery System)

The technique according to the present disclosure (the present technology) is applicable to various products. For example, the technique according to the present disclosure may be applied to an endoscopic surgery system.

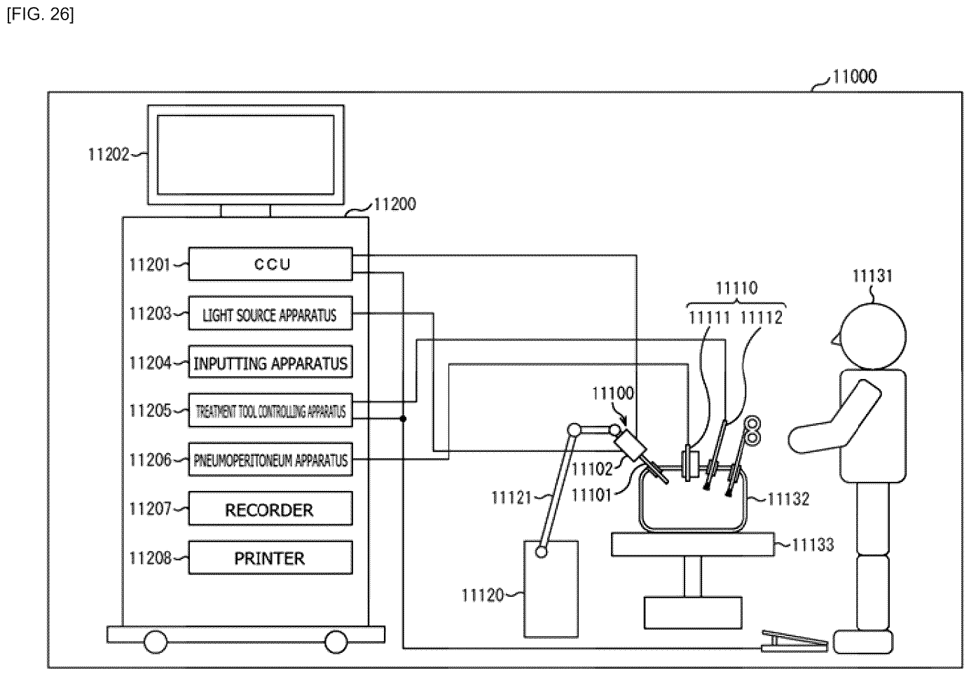

FIG. 26 is a view depicting an example of a schematic configuration of an endoscopic surgery system to which the technology according to an embodiment of the present disclosure (present technology) can be applied.

In FIG. 26, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

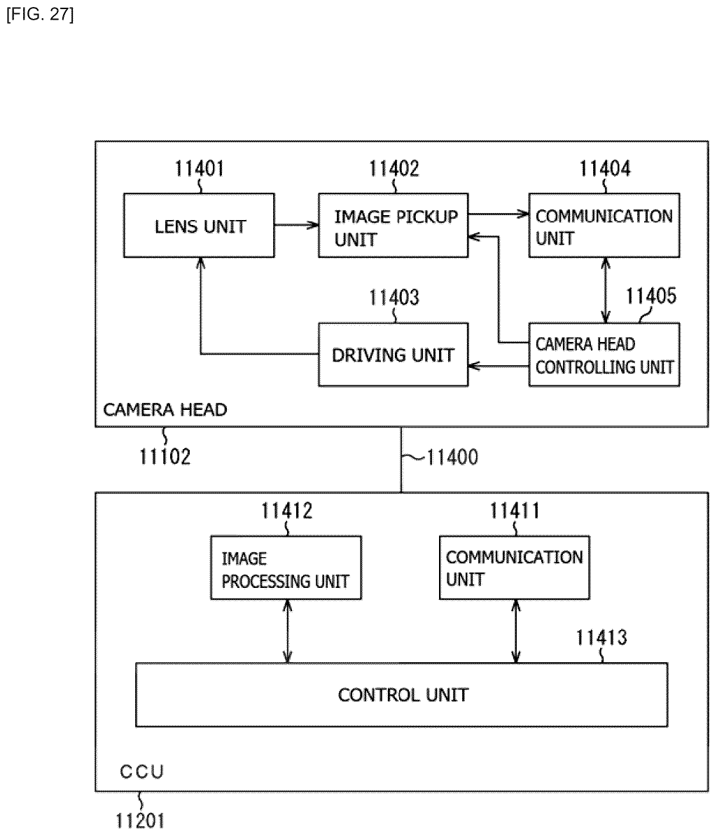

FIG. 27 is a block diagram depicting an example of a functional configuration of the camera head 11102 and the CCU 11201 depicted in FIG. 26.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As above, there has been described an example of the endoscopic surgery system to which the technique according to the present disclosure may be applied. The technique according to the present disclosure may be suitably applied to, of the above-described components, for example, the image pickup unit 11402 provided in the camera head 11102 of the endoscope 11100. By applying the technique according to the present disclosure to the image pickup unit 11402, it becomes possible to make the image pickup unit 11402 highly sensitive; therefore, it is possible to provide the high-definition endoscope 11100.

The present disclosure has been described above with the embodiments, the modification examples, the examples of use, and the application examples; however, the present technology is not limited to the above-described embodiments, etc., and it is possible to make various modifications. For example, the above-described modification examples have been described as modification examples of the above-described embodiments; furthermore, it is possible to fittingly combine respective configurations of the modification examples. For example, the present disclosure is not limited to a back-illuminated image sensor, and is also applicable to a front-illuminated image sensor.

An imaging device of one embodiment of the present disclosure includes: a plurality of pixels each including a first photoelectric converter configured to generate an electric charge by photoelectric conversion, an accumulation unit configured to accumulate an electric charge into which light has been photoelectrically converted, a capacitive element configured to accumulate an overflowed electric charge, a first transistor provided between the capacitive element and the accumulation unit, and a second transistor configured to output a signal based on the electric charge accumulated in the accumulation unit; and a signal line coupled to second transistors of the plurality of pixels. Thus, it is possible to expand the dynamic range.

It is to be noted that the effects described in the present specification are merely an example; the effects of the present disclosure are not limited to those described in the specification, and the present disclosure may have other effects. Furthermore, the present disclosure may have the following configuration.

(1)

An imaging device including:
a plurality of pixels each including a first photoelectric converter configured to generate an electric charge by photoelectric conversion, an accumulation unit configured to accumulate an electric charge into which light has been photoelectrically converted, a capacitive element configured to accumulate an overflowed electric charge, a first transistor provided between the capacitive element and the accumulation unit, and a second transistor configured to output a signal based on the electric charge accumulated in the accumulation unit; and
a signal line coupled to the second transistors of the plurality of pixels.
   (2)

The imaging device according to (1), in which
the second transistor is an amplifier transistor coupled to a power supply line and configured to output the signal based on the electric charge accumulated in the accumulation unit to the signal line.
   (3)

The imaging device according to (1) or (2), in which
the pixels each include a second photoelectric converter configured to generate an electric charge by photoelectric conversion, and
the capacitive element is configured to accumulate an electric charge overflowed from the second photoelectric converter.
   (4)

The imaging device according to (3), in which
a sensibility of the second photoelectric converter to light is lower than a sensibility of the first photoelectric converter to light.
   (5)

The imaging device according to (3) or (4), in which
the pixels each include a third transistor provided between the second photoelectric converter and the capacitive element, and
the capacitive element is configured to accumulate the electric charge overflowed from the second photoelectric converter through the third transistor.
   (6)

The imaging device according to any one of (3) to (5), in which
the pixels each include a fourth transistor configured to reset a voltage of the accumulation unit.
   (7)

The imaging device according to (6), in which
the second transistor has a gate electrically coupled to the accumulation unit, and
the fourth transistor is electrically coupled to a power supply line through which a first voltage or a second voltage lower than the first voltage is configured to be transmitted, and is configured to supply the first voltage or the second voltage to the accumulation unit.
   (8)

The imaging device according to (6) or (7), in which
a first electrode of the capacitive element is electrically coupled to the second photoelectric converter, and
a second electrode of the capacitive element and the fourth transistor are electrically coupled to a shared power supply line.
   (9)

The imaging device according to (6) or (7), in which
a first electrode of the capacitive element is electrically coupled to the second photoelectric converter, and
a second electrode of the capacitive element and the fourth transistor are electrically coupled to different power supply lines from each other.
   (10)

The imaging device according to (1) or (2), in which
the capacitive element is configured to accumulate an electric charge overflowed from the first photoelectric converter.
   (11)

The imaging device according to (10), in which
the pixels each include a fifth transistor provided between the first photoelectric converter and the capacitive element, and
the capacitive element is configured to accumulate the electric charge overflowed from the first photoelectric converter through the fifth transistor.
   (12)

The imaging device according to (10) or (11), in which
the pixels each include a fourth transistor configured to reset a voltage of the accumulation unit.
   (13)

The imaging device according to (12), in which
the second transistor has a gate electrically coupled to the accumulation unit, and
the fourth transistor is electrically coupled to a power supply line through which a first voltage or a second voltage lower than the first voltage is configured to be transmitted, and is configured to supply the first voltage or the second voltage to the accumulation unit.
   (14)

The imaging device according to (12) or (13), in which
a first electrode of the capacitive element is electrically coupled to the first photoelectric converter, and
a second electrode of the capacitive element and the fourth transistor are electrically coupled to a shared power supply line.
   (15)

The imaging device according to (12) or (13), in which
a first electrode of the capacitive element is electrically coupled to the first photoelectric converter, and
a second electrode of the capacitive element and the fourth transistor are electrically coupled to different power supply lines from each other.
   (16)

The imaging device according to any one of (1) to (15), including:
a substrate provided with a plurality of the first photoelectric converters; and
a separation section provided between the first photoelectric converters adjacent to each other.
   (17)

The imaging device according to (16), in which
the separation section goes through the substrate between the first photoelectric converters adjacent to each other.
   (18)

The imaging device according to (16) or (17), including the substrate provided with the plurality of the first photoelectric converters,
in which the pixels each include a transfer unit configured to transfer the electric charge into which light has been photoelectrically converted by the first photoelectric converter to the accumulation unit, and
the transfer unit is formed by digging in the substrate.
   (19)

The imaging device according to (18), including
an oxide film provided to surround the transfer unit in the substrate.
   (20)

A method for driving an imaging device, the imaging device including a plurality of pixels each including a photoelectric converter configured to generate an electric charge by photoelectric conversion, an accumulation unit configured to accumulate an electric charge, a capacitive element configured to accumulate an overflowed electric charge, and a transistor configured to output a signal based on the electric charge accumulated in the accumulation unit and a signal line coupled to the transistors of the plurality of pixels,
the method including:
   transferring at least one of the electric charge into which light has been photoelectrically converted by the photoelectric converter and the electric charge accumulated in the capacitive element to the accumulation unit; and
outputting, by the transistor, a signal based on the electric charge accumulated in the accumulation unit to the signal line.

The present application claims the benefit of Japanese Priority Patent Application JP2022-018255 filed with the Japan Patent Office on Feb. 8, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a plurality of pixels each including a first photoelectric converter configured to generate an electric charge by photoelectric conversion, an accumulation unit configured to accumulate an electric charge into which light has been photoelectrically converted, a capacitive element configured to accumulate an overflowed electric charge, a first transistor provided between the capacitive element and the accumulation unit, and a second transistor configured to output a signal based on the electric charge accumulated in the accumulation unit; and
a signal line coupled to the second transistors of the plurality of pixels.

2. The imaging device according to claim 1, wherein
the second transistor is an amplifier transistor coupled to a power supply line and configured to output the signal based on the electric charge accumulated in the accumulation unit to the signal line.

3. The imaging device according to claim 1, wherein
the pixels each include a second photoelectric converter configured to generate an electric charge by photoelectric conversion, and
the capacitive element is configured to accumulate an electric charge overflowed from the second photoelectric converter.

4. The imaging device according to claim 3, wherein
a sensibility of the second photoelectric converter to light is lower than a sensibility of the first photoelectric converter to light.

5. The imaging device according to claim 3, wherein
the pixels each include a third transistor provided between the second photoelectric converter and the capacitive element, and
the capacitive element is configured to accumulate the electric charge overflowed from the second photoelectric converter through the third transistor.

6. The imaging device according to claim 3, wherein
the pixels each include a fourth transistor configured to reset a voltage of the accumulation unit.

7. The imaging device according to claim 6, wherein
the second transistor has a gate electrically coupled to the accumulation unit, and
the fourth transistor is electrically coupled to a power supply line through which a first voltage or a second voltage lower than the first voltage is configured to be transmitted, and is configured to supply the first voltage or the second voltage to the accumulation unit.

8. The imaging device according to claim 6, wherein
a first electrode of the capacitive element is electrically coupled to the second photoelectric converter, and
a second electrode of the capacitive element and the fourth transistor are electrically coupled to a shared power supply line.

9. The imaging device according to claim 6, wherein
a first electrode of the capacitive element is electrically coupled to the second photoelectric converter, and
a second electrode of the capacitive element and the fourth transistor are electrically coupled to different power supply lines from each other.

10. The imaging device according to claim 1, wherein
the capacitive element is configured to accumulate an electric charge overflowed from the first photoelectric converter.

11. The imaging device according to claim 10, wherein
the pixels each include a fifth transistor provided between the first photoelectric converter and the capacitive element, and
the capacitive element is configured to accumulate the electric charge overflowed from the first photoelectric converter through the fifth transistor.

12. The imaging device according to claim 10, wherein
the pixels each include a fourth transistor configured to reset a voltage of the accumulation unit.

13. The imaging device according to claim 12, wherein
the second transistor has a gate electrically coupled to the accumulation unit, and
the fourth transistor is electrically coupled to a power supply line through which a first voltage or a second voltage lower than the first voltage is configured to be transmitted, and is configured to supply the first voltage or the second voltage to the accumulation unit.

14. The imaging device according to claim 12, wherein
a first electrode of the capacitive element is electrically coupled to the first photoelectric converter, and
a second electrode of the capacitive element and the fourth transistor are electrically coupled to a shared power supply line.

15. The imaging device according to claim 12, wherein
a first electrode of the capacitive element is electrically coupled to the first photoelectric converter, and
a second electrode of the capacitive element and the fourth transistor are electrically coupled to different power supply lines from each other.

16. The imaging device according to claim 1, comprising:
a substrate provided with a plurality of the first photoelectric converters; and
a separation section provided between the first photoelectric converters adjacent to each other.

17. The imaging device according to claim 16, wherein
the separation section goes through the substrate between the first photoelectric converters adjacent to each other.

18. The imaging device according to claim 1, comprising a substrate provided with a plurality of the first photoelectric converters,
wherein the pixels each include a transfer unit configured to transfer the electric charge into which light has been photoelectrically converted by the first photoelectric converter to the accumulation unit, and
the transfer unit is formed by digging in the substrate.

19. The imaging device according to claim 18, comprising
an oxide film provided to surround the transfer unit in the substrate.

20. A method for driving an imaging device, the imaging device including a plurality of pixels each including a photoelectric converter configured to generate an electric charge by photoelectric conversion, an accumulation unit configured to accumulate an electric charge, a capacitive element configured to accumulate an overflowed electric charge, and a transistor configured to output a signal based on the electric charge accumulated in the accumulation unit and a signal line coupled to the transistors of the plurality of pixels, the method comprising:
transferring at least one of the electric charge into which light has been photoelectrically converted by the photoelectric converter and the electric charge accumulated in the capacitive element to the accumulation unit; and
outputting, by the transistor, a signal based on the electric charge accumulated in the accumulation unit to the signal line.
